(19) United States
(12) Patent Application Publication
(10) Pub. No.: US 2024/0377483 A1
(43) Pub. Date: Nov. 14, 2024

(54) MAGNETIC SENSOR, AND STATE DETECTION APPARATUS AND METHOD

(71) Applicant: SUZHOU NOVOSENSE MICROELECTRONICS CO., LTD., Suzhou (CN)

(72) Inventor: Fute YUAN, Suzhou (CN)

(73) Assignee: SUZHOU NOVOSENSE MICROELECTRONICS CO., LTD., Suzhou (CN)

(21) Appl. No.: 18/660,739

(22) Filed: May 10, 2024

(30) Foreign Application Priority Data
May 12, 2023 (CN) 202310538161.5

(51) Int. Cl. G01R 33/09; G01R 33/00; G01R 33/07

(52) U.S. Cl. CPC G01R 33/091; G01R 33/0005; G01R 33/072

(57) ABSTRACT

The present invention discloses a magnetic sensor and a state detection apparatus and method. The magnetic sensor comprises a sensing assembly and a base plate. The sensing assembly comprises a magnetic aggregation element and at least one sensing element adjacent to an extension surface of the magnetic aggregation element. At least two sensing assemblies are arranged on a carrying surface of the base plate. When the magnetic sensor approaches a magnet to be detected, one of the sensing assemblies is relatively close to a first magnetic pole of the magnet to be detected and another of the sensing assemblies is relatively away from the first magnetic pole, at least in a first state. The magnetic sensor provided by the present invention can give consideration to both the anti-interference performance and the universal application of the device, and can eliminate restrictions in manufacture and use of traditional magnetic sensors.

### TECHNICAL FIELD

The present invention relates to the field of test and measurement technologies, and more particularly to a magnetic sensor and a state detection apparatus and method.

### BACKGROUND

Technologies for detecting the current state of an object, particularly technologies for detecting data related to the motion state or position state of the object, play an important role in the industrial, automotive, and commercial fields, and can realize monitoring and alarming of various systems, such as idling and sliding, and various automatic action feedback control including action or attitude control or triggering of various operations. In particular, the detection of the current state can be achieved by measuring magnetic signals. A magnetic medium can be used for preparing the object to be detected, or a magnetic material can be placed at the object to be detected, thus achieving the advantages of non-contact measurement, excellent anti-vibration, anti-wear and anti-oil features, and ability to provide sufficient accuracy and reaction speed.

According to a technical solution provided in the prior art, in one aspect, based on the distribution rules of magnetic induction lines, usually a sensor needs to be configured to have at least a horizontal sensing direction to complete state detection. Considering the sensor accuracy and the more extensive application status quo of vertical magnetic sensors on the market, this solution will undoubtedly increase the cost and be detrimental to the accuracy of detection results. In another aspect, regardless of whether the magnetic sensor has a vertical or horizontal sensing direction, one sensing direction may be possibly interfered by the other sensing direction, leading to deterioration of the detection effect.

### SUMMARY OF THE INVENTION

One objective of the present invention is to provide a magnetic sensor to solve the technical problems in the prior art that a magnetic sensor is restricted in manufacture and use, cannot resist other interference and thus is low in detection accuracy.

Another objective of the present invention is to provide a state detection apparatus.

Yet another objective of the present invention is to provide a state detection method.

To fulfill one of the above objectives of the present invention, an embodiment of the present invention provides a magnetic sensor, including a sensing assembly including a magnetic aggregation element and at least one sensing element adjacent to an extension surface of the magnetic aggregation element; a base plate, on a carrying surface of which at least two of the sensing assemblies are arranged; and when the magnetic sensor approaches a magnet to be detected, one of the sensing assemblies is relatively close to a first magnetic pole of the magnet to be detected and another of the sensing assemblies is relatively away from the first magnetic pole, at least in a first state.

In order to fulfill one of the above objectives, an embodiment of the present invention provides a state detection apparatus, including a magnetic sensor as described in any one of the technical solutions in the present invention. The state detection apparatus is configured to determine, according to an output of the magnetic sensor, current state data of a magnet to be detected; wherein the state data includes at least one of angle, velocity, acceleration and rotation stroke length.

In order to fulfill one of the above objectives, an embodiment of the present invention provides a state detection method applied to the magnetic sensor as described in any one of the technical solutions in the present invention. The state detection method includes: receiving a first intermediate signal and a second intermediate signal, wherein the first intermediate signal is formed at a first sensing element group arranged in a first sensing assembly in a first direction, the second intermediate signal is formed at a second sensing element group arranged in a second sensing assembly in the first direction, one of the first sensing assembly and the second sensing assembly is relatively close to the first magnetic pole, and the other of the first sensing assembly and the second sensing assembly is relatively away from the first magnetic pole; and performing at least a second operation according to the first intermediate signal and the second intermediate signal to determine first state data of the magnet to be detected.

Compared with the prior art, the magnetic sensor provided by the present invention enables adjustment of the directions of magnetic induction lines at the sensing elements by arranging the magnetic aggregation elements near the sensing elements, thereby being suitable for the sensing elements with different sensing directions, and eliminating restrictions in manufacture and use of the magnetic sensor. According to the magnetic sensor provided by the present invention, the two sets of sensing assemblies having different relative positional relationships with the first magnetic pole on the magnet to be detected can form a contrast with each other to achieve an anti-interference effect.

### BRIEF DESCRIPTION OF THE DRAWINGS

FIG. 1 is a schematic diagram of a first positional relationship between a magnetic sensor and a magnet to be detected according to an embodiment of the present invention;

FIG. 2 is a schematic diagram of a second positional relationship between a magnetic sensor and a magnet to be detected according to an embodiment of the present invention;

FIG. 3 is a schematic structural diagram of a magnetic sensor according to an embodiment of the present invention;

FIG. 4 is a schematic structural diagram of a first example of a sensing assembly or a reference assembly according to an embodiment of the present invention;

FIG. 5 is a sectional view of a first example of the sensing assembly or the reference assembly along a first section line R1 in FIG. 4 according to an embodiment of the present invention;

FIG. 6 is a schematic structural diagram of a second example of a sensing assembly or a reference assembly according to an embodiment of the present invention;

FIG. 7 is a schematic structural diagram of a third example of a sensing assembly or a reference assembly according to an embodiment of the present invention;

FIG. 8 is a schematic structural diagram of a fourth example of a reference assembly according to an embodiment of the present invention;

FIG. 9 is a schematic structural diagram of a magnetic sensor according to a first embodiment of the present invention;

FIG. 10 is a sectional view of the magnetic sensor along a second section line R2 in FIG. 9 according to the first embodiment of the present invention;

FIG. 11 is a diagram showing distribution of magnetic induction lines on a section of a sensing assembly or a reference assembly along a second section line R2 in FIG. 9 under a third-direction magnetic field according to the first embodiment of the present invention;

FIG. 12 is a diagram showing distribution of magnetic induction lines on a section of a sensing assembly or a reference assembly along a second section line R2 in FIG. 9 under a first-direction magnetic field according to the first embodiment of the present invention;

FIG. 13 is a diagram showing distribution of magnetic induction lines on a section of a reference assembly along a third section line R3 in FIG. 9 under a third-direction magnetic field according to the first embodiment of the present invention;

FIG. 14 is a diagram showing distribution of magnetic induction lines on a section of a reference assembly along a third section line R3 in FIG. 9 under a first-direction magnetic field according to the first embodiment of the present invention;

FIG. 15 is a schematic structural diagram of a state detection apparatus according to a first embodiment of the present invention;

FIG. 16 is a waveform diagram of a magnetic signal output by a magnetic sensor in a case of no interference according to a first embodiment of the present invention;

FIG. 17 is a waveform diagram of a magnetic signal output by a magnetic sensor in a case of interference according to a first embodiment of the present invention;

FIG. 18 is a schematic structural diagram of a magnetic sensor according to a second embodiment of the present invention;

FIG. 19 is a sectional view of the magnetic sensor along a fourth section line R4 in FIG. 18 according to the second embodiment of the present invention;

FIG. 20 is a schematic structural diagram of a state detection apparatus according to a second embodiment of the present invention;

FIG. 21 is a schematic structural diagram of a magnetic sensor according to another embodiment of the present invention;

FIG. 22 is a schematic structural diagram of a magnetic sensor according to a third embodiment of the present invention;

FIG. 23 is a schematic structural diagram of a state detection apparatus according to a fourth embodiment of the present invention;

FIG. 24 is a schematic structural diagram of a magnetic sensor according to a fourth embodiment of the present invention;

FIG. 25 is a schematic structural diagram of a state detection apparatus according to a fourth embodiment of the present invention;

FIG. 26 is a schematic structural diagram of a first example of a sensing element or a reference element according to an embodiment of the present invention;

FIG. 27 is a schematic structural diagram of a second example of a sensing element or a reference element according to an embodiment of the present invention;

FIG. 28 is a schematic structural diagram of a third example of a sensing element or a reference element according to an embodiment of the present invention;

FIG. 29 is a schematic structural diagram of a fifth example of a sensing assembly or a reference assembly according to an embodiment of the present invention;

FIG. 30 is a schematic diagram of steps of a state detection method according to an embodiment of the present invention;

FIG. 31 is a schematic diagram of steps of a first example of a state detection method according to an embodiment of the present invention;

FIG. 32 is a schematic diagram of steps of a second example of a state detection method according to an embodiment of the present invention;

FIG. 33 is a schematic diagram of steps of a third example of a state detection method according to an embodiment of the present invention;

FIG. 34 is a schematic structural diagram of a test and measurement system according to a first embodiment of the present invention;

FIG. 35 is a schematic structural diagram of a test and measurement system according to a second embodiment of the present invention; and

FIG. 36 is a schematic structural diagram of a test and measurement system according to a third embodiment of the present invention.

### DETAILED DESCRIPTION

The present invention will be described in detail below in combination with specific embodiments shown in the drawings. However, these embodiments do not limit the present invention, and all structural, method or functional variations made by those of ordinary skills in the art according to these embodiments shall be included in the protection scope of the present invention.

It should also be noted that the terms “comprise/include” or any other variants in the present invention are intended to cover the nonexclusive containing, such that the processes, methods, articles or apparatuses including a series of elements not only include those elements, but also include other unclearly listed elements, or also include the inherent elements of such processes, methods, articles or apparatuses. Without more limitations, the element defined by the phrase “including a . . . ” does not exclude the existence of other same elements in the process, method, article or apparatus that includes such element. In addition, the terms “first”, “second”, “third”, “fourth, “fifth”, “sixth”, “seventh” and the like are only for the purpose of description and should not be understood as indicating or implying relative importance.

Sensors for detecting state data such as angle, stroke, velocity and direction can be used in a wide range of scenarios, such as measuring gear rotation in mechanical devices and measuring stroke of valve switches. This makes it possible to detect idling slides in automobiles and other apparatuses including wheeled devices, and also to detect action feedback of automated production lines.

In order to adapt to a wide range of difficult operating conditions, it is necessary to use a state data measurement method, which can perform non-contact measurement and resist vibration and oil contamination and is high in accuracy and quick in response. Therefore, using a magnetic sensor for detection is a preferred choice. Magnetic sensors can usually be categorized into components made on the principle of the Hall effect and components made on the principle of the magneto-resistive effect. The magnetic sensors made on the principle of the Hall effect have the advantages of strong compatibility with the complementary metal oxide semiconductor (CMOS) process, small size and high cost performance, while the magnetic sensors made on the principle of the magneto-resistive effect has higher sensitivity, lower integrated circuit (IC) power consumption and higher detection accuracy. Any of the above-mentioned magnetic sensors or other not-mentioned sensors that can be used for sensing physical data can be alternatively applied to any of the embodiments of the present invention provided hereinafter with their own advantages as beneficial effects.

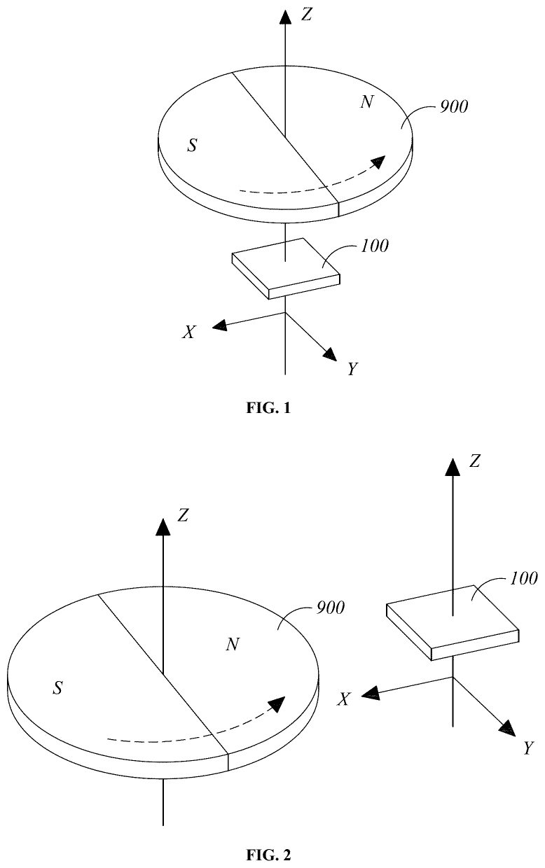

In detecting a magnet to be detected or an object containing the magnet to be detected, the magnetic sensor and the magnet to be detected may have a relative positional relationship as shown in FIG. 1 and/or FIG. 2.

The magnet to be detected 900 may be relatively stationary, and the magnetic sensor 100 may determine, by detecting the distribution of a magnetic field formed thereon by the magnet to be detected 900, the current position or attitude of the magnet to be detected 900. The magnet to be detected 900 may rotate around an axis, and the magnetic sensor 100 may determine a state such as a rotational angle, a rotational speed, or a rotational path of the magnet to be detected 900 according to changes in the magnetic field. The magnet to be detected 900 may revolve around an axis or an object, and the magnetic sensor 100 may determine the states such as a revolution angle, a revolution speed and a revolution path of the magnet to be detected 900 according to changes in the magnetic field.

In other scenarios, the movement of the magnet to be detected 900 may also include translation. Alternatively, the magnet to be detected 900 remains relatively stationary, while the magnetic sensor 100 translates and/or rotates relative to the magnet to be detected 900. the above-mentioned movement of the magnet to be detected 900 can be interpreted as relative movement of the magnet to be detected 900 with respect to the magnetic sensor 100, and therefore, movement of either of the two, or movement of both of the two, is also included in the scope of protection of the present invention.

As shown in FIG. 1, the magnetic sensor 100 may be arranged at one side of the magnet to be detected 900 in a third direction Z; and when the third direction Z is defined as “up” and an opposite direction of the third direction Z is defined as “down”, the magnetic sensor 100 may be arranged above or below the magnet to be detected 900.

In a case where the magnetic sensor 100 and the magnet to be detected 900 are spaced apart in a height direction of the magnetic sensor 100, the magnet to be detected 900 may be interpreted as being arranged at one side of the magnetic sensor 100 in the height direction. In an embodiment, the third direction Z and its opposite direction may be interpreted as the same concept as the height direction of the magnetic sensor 100.

A magnet central axis may be made across a center of the magnet to be detected 900, and a sensor central axis may be made across a center of the magnetic sensor 100. The “center” may be the geometric center or the center of gravity of the magnet to be detected 900 or the magnetic sensor 100. In an embodiment, for the magnet to be detected 900, the above-mentioned center is the center of its magnetic pole interface. In a case where the magnet to be detected 900 includes two magnetic poles, the magnetic pole interface points to the intersection of the two magnetic poles; and in the case where the magnet to be detected 900 is composed of a magnetic monopole, the magnetic pole interface may be any surface of the magnet to be detected 900.

The magnet central axis and the sensor central axis may coincide. The center of the magnet to be detected 900 and the center of the magnetic sensor 100 may be aligned. The alignment may be in a first direction X, a second direction Y or the third direction Z, or be in the height direction or a width direction of the magnetic sensor 100. For example, it is considered that the height direction of the magnetic sensor 100 is the third direction Z, and a sensor plane parallel to both of the first direction X and the second direction Y may be made across the center of the magnetic sensor 100. At this time, the center of the magnetic sensor 100 and the center of the magnet to be detected 900 are aligned in the width direction of the magnetic sensor 100, which can be interpreted as that a projection of the center of the magnet to be detected 900 onto the sensor plane coincides with the center of the magnetic sensor 100.

As shown in FIG. 2, the magnetic sensor 100 may be arranged at one side of the magnet to be detected 900 in the first direction X; and in a case where the first direction X is defined as “left” and the opposite direction of the first direction is defined as “right”, the magnetic sensor 100 may be arranged at the left or right side of the magnet to be detected 900. The magnetic sensor 100 may be arranged at one side of the magnet to be detected 900 in the second direction Y; and in a case where the second direction Y is defined as “front” and the opposite direction (as shown by −Y in FIGS. 10 to 14 and 19) of the second direction is defined as “behind”, the magnetic sensor 100 may be arranged in front of or behind the magnet to be detected 900.

In a case where the magnetic sensor 100 and the magnet to be detected 900 are spaced apart in the width direction of the magnetic sensor 100, the magnet to be detected 900 may be interpreted as being arranged at one side in the width direction of the magnetic sensor 100. In an embodiment, the first direction X and its opposite direction, and the second direction Y and its opposite direction −Y may be interpreted as the same concept as the width direction of the magnetic sensor 100.

The center of the magnet to be detected 900 and the center of magnetic sensor 100 may be aligned in the third direction Z and may also be aligned in the height direction of the magnetic sensor 100. For example, it is considered that the height direction of the magnetic sensor 100 is the third direction Z, and a sensor plane parallel to the magnetic pole interface of the magnet to be detected 900 may be made across the center of the magnetic sensor 100. At this time, the center of the magnetic sensor 100 and the center of the magnet to be detected 900 are aligned in the height direction of the magnetic sensor 100, which can be interpreted as that a projection of the center of the magnet to be detected 900 onto the sensor plane coincides with the center of the magnetic sensor 100.

An embodiment of the present invention provides a state detection apparatus, including a magnetic sensor 100.

The state detection apparatus may be configured to determine, according to an output of the magnetic sensor 100, current state data of a magnet to be detected 900. The state data includes at least one of an angle at which the magnet to be detected 900 is currently located, a change in angle of the magnet to be detected 900, velocity or acceleration of movement of the magnet to be detected 900, or length of a rotational path (e.g., rotation stroke length) occurring as a result of rotation or revolution of the magnet to be detected 900. Although explanations are made hereinafter by defining the state data as angle data formed by rotation of the magnet to be detected 900 around its magnet central axis, the range of detection of the state data, actually supported by the present invention, is not limited thereto.

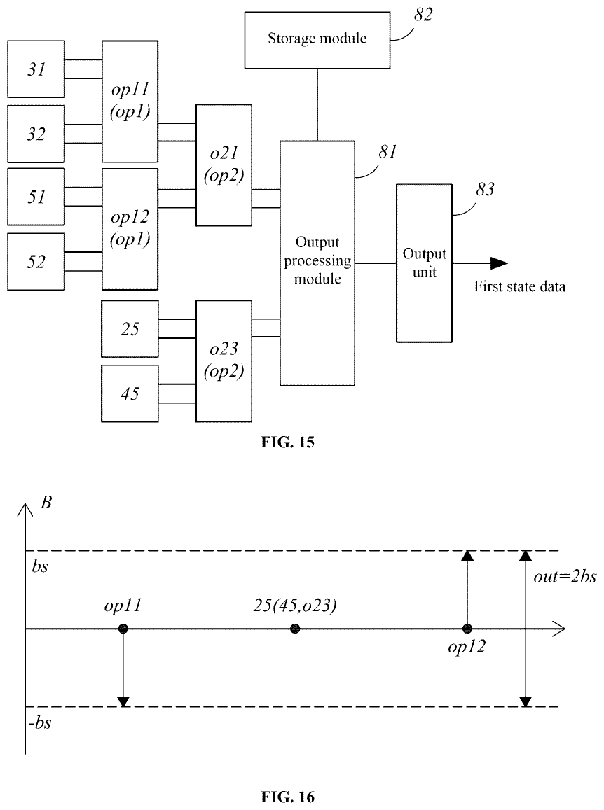

As shown in FIGS. 15, 20, 23 and 25, in an embodiment, the state detection apparatus further includes a storage module 82 and an output processing module 81. In an example, the state detection apparatus includes an output unit 83.

The storage module 82 is configured to store state correction information. The state correction information may be interpreted as information for correcting the state data. In an embodiment in which the state detection apparatus is further provided with other controlled devices in a backward stage, and the controlled devices are configured to control and correct themselves or their backward-stage devices according to the state data output by the state detection apparatus, the state correction information may also be interpreted as information for correcting the controlled devices or their backward-stage devices.

In an embodiment, the output processing module 81 is coupled to the magnetic sensor. In an implementation example, the output processing module 81 may be coupled to a sensing assembly of the magnetic sensor, such as a sensing element 31 and a sensing element 32 in a first sensing element group of a first sensing assembly, or a sensing element 51 and a sensing element 52 in a second sensing element group of a second sensing assembly.

The output processing module 81 is configured to receive an output signal of the magnetic sensor. The output signal may be an output signal of a single sensing assembly or an output signal of a single sensing element. The output processing module 81 is configured to calculate the state data according to the output signal of the magnetic sensor. The state data may include first state data corresponding to a first state of the magnet to be detected 900.

In another embodiment, the output processing module 81 is coupled to the magnetic sensor and the storage module 82. The output processing module 81 is configured to receive an output signal of the magnetic sensor and calculate the state data according to the output signal of the magnetic sensor. The output processing module 81 is configured to adjust the state data according to the state correction information.

Other features of the state detection apparatus will be described later corresponding to the magnetic sensor, and will not be repeated herein. Various embodiments or examples provided below may be juxtaposed or combined with each other to form a unified solution. In this unified solution, switching of the state detection apparatus between different configuration solutions may be realized by a switching device, and the switching device may be configured to at least adjust the connection relationship between modules.

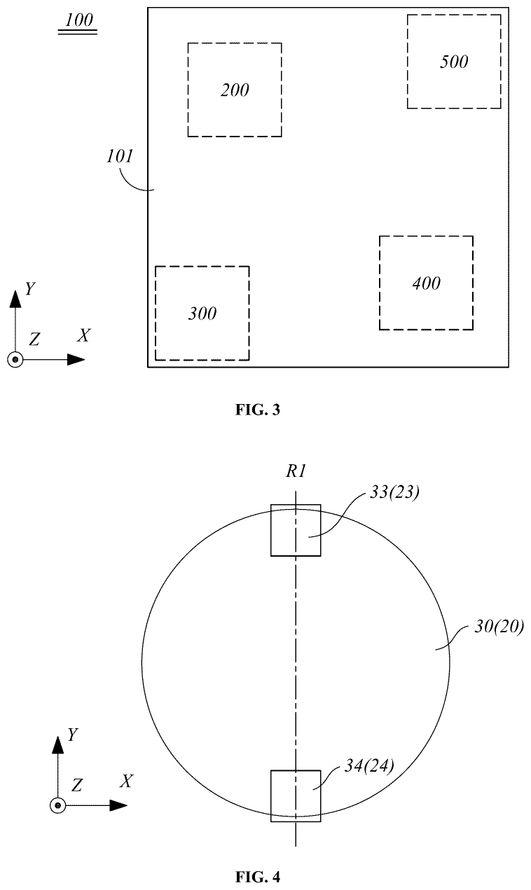

As shown in FIGS. 3, 6, 9, 10, 18, 19, 21, 22 and 24 in combination with FIGS. 4, 5, 7, 11 and 12, an embodiment of the present invention provides a magnetic sensor 100, which may be applied to the state detection apparatus described in any of the above technical solutions and on which a state detection method as described later may also be implemented.

The magnetic sensor 100 may include a sensing assembly and a base plate 101. In order to simplify the expression, by taking either a first sensing assembly 300 or the first sensing assembly 300 and a second sensing assembly 500 as an example, the sensing assembly provided by the present invention will be defined by describing the first sensing assembly 300 or the second sensing assembly 500. The definition of the sensing assembly does not imply that the devices therein are necessarily packaged as a whole. In an embodiment in which no integral package occurs, the following descriptions of the sensing assembly can be interpreted as descriptions of an area in the magnetic sensor 100 for arranging the devices contained in the sensing assembly. The sensing assembly is interpreted as an area at the magnetic sensor 100 for realizing sensing.

The sensing assembly includes a magnetic aggregation element and a at least one sensing element adjacent to an extension surface of the magnetic aggregation element. For example, the first sensing assembly 300 includes a first magnetic aggregation element 30, and at least one sensing element, for example, a sensing element 31 or a sensing element 32. The sensing element 31 and the sensing element 32 are adjacent to an extension surface of the first magnetic aggregation element 30. In an embodiment, a magnetic field of the magnet to be detected 900 near the extension surface is deflected in a direction of the extension surface due to a magnetic aggregation function of the first magnetic aggregation element 30.

The magnetic aggregation element may be prepared from a ferromagnetic material. The ferromagnetic material is preferably permalloy, ferro-nickel high-permeability alloy or metallic glass. In a preferred embodiment, the ferromagnetic material is metallic glass with low coercive field strength, which can avoid a hysteresis effect. The degree of magnetization of the magnetic aggregation element may be configured to be substantially isotropic.

In an embodiment, the magnetic aggregation element may extend at an XY plane where the first direction X and the second direction Y are located, and form a relatively flat appearance. At this time, the extension surface of the magnetic aggregation element may be parallel to the XY plane. The magnetic aggregation element has a relatively uniform thickness in the third direction Z or in its height direction, or the thickness in middle of the magnetic aggregation element is slightly greater than the thickness at edge of the magnetic aggregation element.

Correspondingly, the sensing assembly may also extend at a plane parallel to the XY plane, so that the deflection amplitude of the magnetic field, received by the sensing element, may be highly consistent with the deflection amplitude of the magnetic field at the extension surface of the magnetic aggregation element.

At least two of the sensing assemblies are arranged on a carrying surface of the base plate 101. For example, at least the first sensing assembly 300 and the second sensing assembly 500 are arranged on the carrying surface of the base plate 101. In other embodiments, a third sensing assembly may also be arranged on the carrying surface of the base plate 101. In other embodiments, a reference assembly, for example, a first reference assembly 200 or a second reference assembly 400, may also be arranged on the carrying surface of the base plate 101.

The carrying surface may be interpreted as a surface for carrying components. A single base plate 101 may be provided with one or a plurality of carrying surfaces.

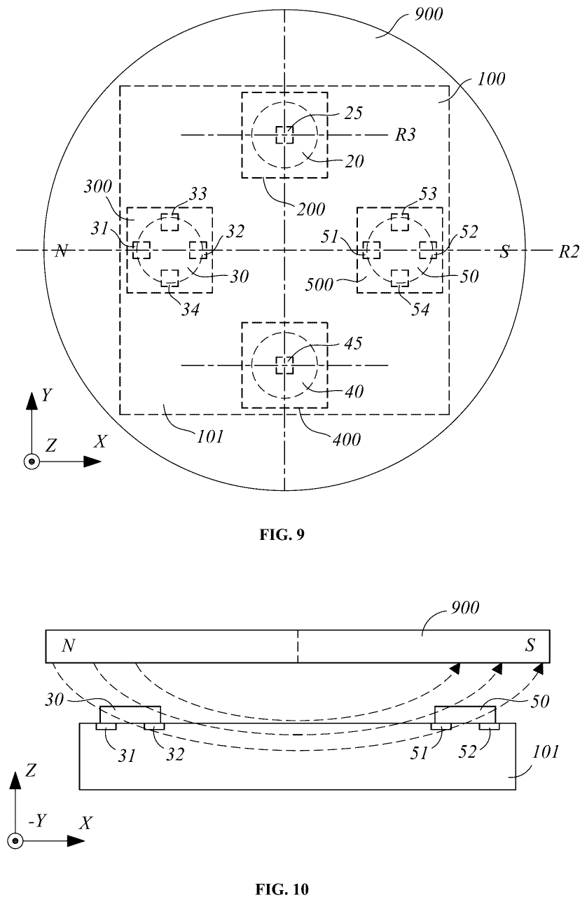

The magnet to be detected 900 may be in the first state when the magnetic sensor 100 approaches the magnet to be detected 900, or when the magnetic sensor 100 detects the magnet to be detected 900. The first state of the magnet to be detected 900 may characterize the magnet as being at a certain current angle, a certain angle change process, a certain uniform motion process, a certain accelerated motion process or a process of rotation through a certain path length. For example, the first state of the magnet to be detected 900 may be the state shown in FIG. 9, 18, 22 or 24.

As shown in FIGS. 3, 6, 9, 10, 18, 19, 21, 22 and 24, at least in the first state, one of the sensing assemblies is relatively close to a first magnetic pole N of the magnet to be detected 100, and another of the sensing assemblies is relatively away from the first magnetic pole N. For example, in an embodiment provided in FIG. 9 or FIG. 22, the first sensing assembly 300 is close to the first magnetic pole N, and the second sensing assembly 500 is further away from the first magnetic pole N than the first sensing assembly 300. If the magnet to be detected 900 rotates by 180 degrees around its central axis, the second sensing assembly 500 is closer to the first magnetic pole N, and the first sensing assembly 300 is further away from the first magnetic pole N. For the magnet to be detected 100 prepared and formed by a magnetic monopole, the whole magnet may be regarded as a first magnetic pole, which can therefore be interpreted as that there exists at least one state, in which one of the sensing assemblies is closer to the magnet to be detected 100, and at least another one of the sensing assemblies is further away from the magnet to be detected 100.

In addition, at least two sensing assemblies have substantially the same sensing direction. Specifically, the sensing elements in the sensing assemblies have the same sensing direction, or the angle between the sensing direction of the two is less than a predetermined threshold. Through performing a second operation on signals formed on the two sensing assemblies, a detection signal carrying the first state data without interference is formed. The second operation may be a differential operation.

The extension surface of the magnetic aggregation element may be defined as a side surface of the magnetic aggregation element adjacent to the carrying surface of the base plate 101. Positional setting solutions that enable adjustment of the direction of the magnetic field at the sensing assembly can all be alternatively implemented in the present invention, and the present invention is not necessarily limited to the above-mentioned technical solution.

In this way, since the sensing element is adjacent to the extension surface of the magnetic aggregation element, the magnetic field of the magnet to be detected 900 near the extension surface is deflected towards the extension surface, and even if the directions of magnetic induction lines of an original magnetic field herein are parallel to the extension surface, a component perpendicular to the extension surface may be generated due to the aggregation effect of the magnetic field. The perpendicular component is reflected on one side of the sensing assembly, so that the sensing element whose sensing direction is always perpendicular to the extension surface may also detect a parallel magnetic field. When the sensing direction of the sensing element is always parallel to the extension surface, but the original magnetic field formed by the magnet to be detected 900 at the magnetic sensor 100 is perpendicular to the extension surface, a deflection component of the magnetic field may also be formed based on the magnetic aggregation element. Therefore, the range of application of the magnetic sensor 100 is expanded, and problems such as structural adjustment, rising cost and decreasing accuracy are avoided.

Since the two sensing assemblies have different positions relative to the first magnetic pole in at least one state, the two sensing assemblies sense two sets of detection signals formed by magnetic-field components in their own sensing directions. Since the difference exists due to different distances between the two sensing assemblies and the first magnetic pole, the detection signals in the sensing directions can be thus selectively retained. Correspondingly, magnetic-field components in other directions are usually shown as evenly distributed interfering magnetic fields, and detection signals formed by the interfering magnetic fields at the two sensing assemblies are the same or difference between the two is less than a predetermined threshold, and can therefore be arithmetically eliminated.

As can be seen, the magnetic sensor 100 provided by the present invention can take into account cost, accuracy optimization, and strong anti-interference performance.

With reference to FIGS. 4, 5, 9-12, 18, 19, 22 and 24, the extension surface of the magnetic aggregation element abuts against the carrying surface of the base plate 101. For example, the extension surface of the first magnetic aggregation element 30 abuts against the carrying surface of the base plate 101, and the extension surface of a second magnetic aggregation element 50 abuts against the carrying surface of the base plate 101. In this way, the magnetic aggregation element can be more fully exposed to the magnetic field than the sensing element, realizing a more adequate adjustment of the direction of the magnetic field.

The sensing element is arranged between the corresponding magnetic aggregation element and the base plate 101. For example, the sensing element 31 and the sensing element 32 in the first sensing element group are arranged between the first magnetic aggregation element 30 and the base plate 101, and the sensing element 51 and the sensing element 52 in the second sensing element group are arranged between the second magnetic aggregation element 50 and the base plate 101. In this way, the direction of the magnetic field can be adjusted by the magnetic aggregation element more adequately, and the magnetic-field component is always generated at the sensing element in accordance with the sensing direction of the sensing element.

With reference to FIGS. 4-7, 9-12, 18, 19, 22, 24 and 29, n sensing elements may be arranged to correspond to a single sensing assembly. In a scenario where there is a need to detect the state data in the width direction of the magnetic sensor, n≥2, thereby assisting in identifying the current state of the magnet to be detected 900.

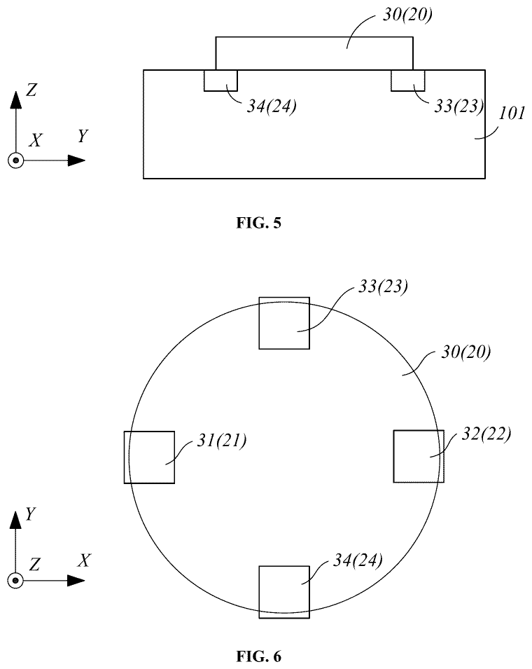

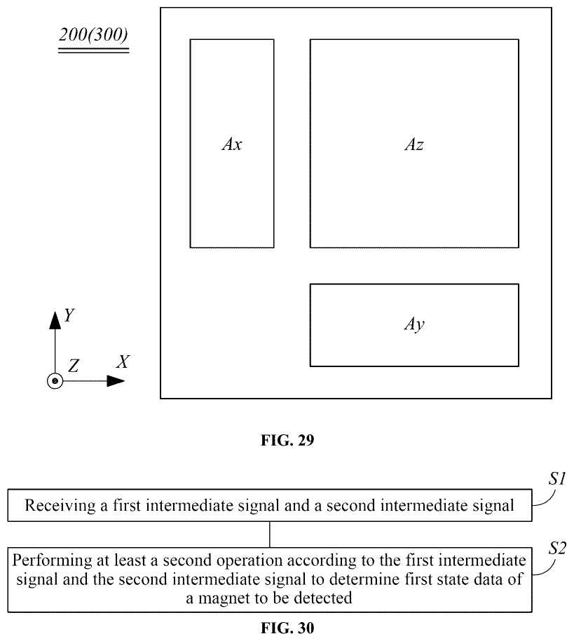

For example, in the embodiment shown in FIGS. 4 and 5, n=2, and the first sensing assembly 300 includes a sensing element 33 and a sensing element 34. For example, in the embodiment shown in FIGS. 6, 9-12, 18, 19, 22 and 24, n=4, the first sensing assembly 300 includes the sensing element 31, the sensing element 32, a sensing element 33 and a sensing element 34, and the second sensing assembly 500 includes the sensing element 51, the sensing element 52, a sensing element 53 and a sensing element 54. For example, in an embodiment shown in FIG. 29, n=3k, where k is a positive integer.

The sensing elements are symmetrically arranged with respect to the centers of the corresponding magnetic aggregation elements. Symmetrical arrangement may be specifically interpreted as below: the sensing elements are arranged axial-symmetrically with respect to any straight line across the centers of the magnetic aggregation elements, and/or the sensing elements are arranged central-symmetrically with respect to projections of the centers of the magnetic aggregation elements onto a plane where the sensing elements are located. In particular, with reference to the XY plane formed in the width direction, the projections of the sensing elements are arranged axial-symmetrically with respect to a projection of any of the straight lines described above, and/or the projections of the sensing elements are arranged central-symmetrically with respect to the projections of the centers of the magnetic aggregation elements. In this way, the detection signal generated by the sensing element at the sensing assembly is regularized by following its symmetrical and standard positional relationship, and the position and the attitude of the magnet to be detected 900 can be determined accordingly.

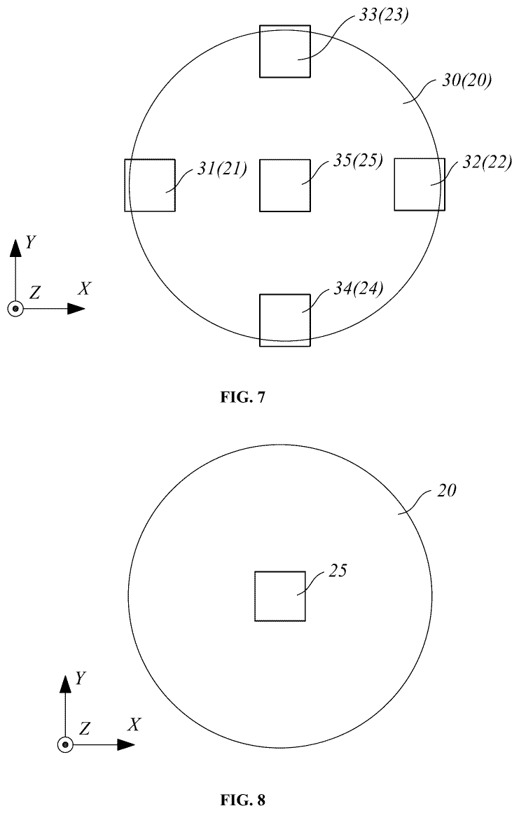

In the embodiment shown in FIG. 7, n may be an odd number, for example, n=5. At this time, preferably, a center (or a central axis) of one of the sensing elements is aligned with a center (or a central axis) of a corresponding magnetic aggregation element, and rest (n-1) sensing elements are symmetrically arranged with respect to a center (or a central axis) of the corresponding magnetic aggregation element. The explanation of the symmetrical arrangement is given above. For example, a center of a sensing element 35 is aligned with a center of the first magnetic aggregation element 30, particularly in the height direction or the third direction Z. The sensing element 31, the sensing element 32, the sensing element 33 and the sensing element 34 are symmetrically arranged with respect to the center of the first magnetic aggregation element 30. In this way, in one aspect, mutual contrast may be formed in the first sensing assembly 300 with the detection signal of the sensing element 35 as a reference; and in another aspect, the sensing element 35 may be disassembled without affecting the shielding effect against the interfering magnetic field.

As shown in FIGS. 1, 9-12 and 22, the magnet to be detected 900 is arranged in the height direction of the magnetic sensor 100. The magnet to be detected 900 is arranged in the third direction Z. In the first state, the sensing assemblies are symmetrical with respect to the magnetic pole interface of the magnet to be detected 900. In an embodiment, the magnet to be detected 900 is arranged at one side of the magnetic sensor 100 in the height direction of the magnetic sensor 100 or in the third direction Z. For example, in the embodiment shown in FIGS. 9 and 10, in the first state, the first sensing assembly 300 and the second sensing assembly 500 are symmetrical with respect to the magnetic pole interface of the magnet to be detected 900. If the first state is interpreted as a position state in which the sensing assemblies are symmetrical with respect to the magnetic pole interface of the magnet to be detected 900 during movement of the magnet to be detected 900, thus, in the embodiment shown in FIG. 22, the first state may be achieved after the magnet to be detected 900 rotates by about 45 degrees clockwise around its central axis.

In such a first state, as shown in FIGS. 10-12, the magnetic-field components in the third direction Z and its opposite direction are set to be in the opposite direction of the third direction Z at the first sensing assembly 300 and to be in the third direction Z at the second sensing assembly 500, and the magnetic-field components in the third direction Z and its opposite direction, formed in the two positions, are equal in absolute value, or their difference in absolute value is less than a predetermined threshold, so that the detection signals retain superposition of original values.

The magnetic-field components in the first direction X and its opposite direction at the magnetic sensor 100 are in the first direction X at the first sensing assembly 300 and the second sensing assembly 300, and the magnetic-field components in the first direction X, formed at the two positions, are equal, or their difference is less than a predetermined threshold. Thus, the magnetic-field components at the two positions can be canceled or superimposed.

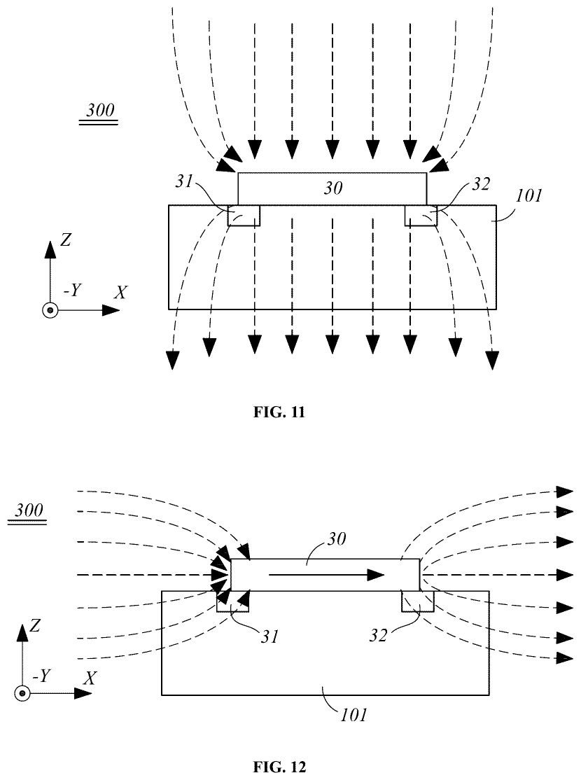

Referring to FIG. 11, even if the magnetic field in the third direction Z and its opposite direction is deflected in the first direction X and its opposite direction due to the existence of the first magnetic aggregation element 30, the deflected magnetic-field components in the first direction X and its opposite direction can be weakened through differential operation due to their opposite in direction, since the first sensing assembly 300 is provided with the sensing element 31 and the sensing element 32 spaced apart on two sides of the first magnetic aggregation element 30 in the first direction X. The sensing element 31 and the second sensing element 32 may be symmetrical with respect to an axis of symmetry of the first magnetic aggregation element 30 in the second direction Y, achieving essentially complete offsetting of the deflected magnetic-field components. The second direction Y is parallel to the extension surface of the first magnetic aggregation element 30 and perpendicular to the first direction X.

Referring to FIG. 12, even if the magnetic field in the first direction X and its opposite direction is deflected in the third direction Z and its opposite direction due to the existence of the first magnetic aggregation element 30, the deflected magnetic-field components in the third direction Z and its opposite direction can be weakened through differential operation due to their opposite in direction, since the first sensing assembly 300 is provided with the sensing element 31 and the sensing element 32 spaced apart on two sides of the first magnetic aggregation element 30 in the first direction X. The sensing element 31 and the sensing element 32 may be axially symmetrical with respect to the projection of the axis of symmetry of the first magnetic aggregation element 30 in the second direction Y onto the sensing element 31 and the sensing element 32, achieving essentially complete offsetting of the deflected magnetic-field components. The second direction Y is parallel to the extension surface of the first magnetic aggregation element 30 and perpendicular to the first direction X.

As shown in FIGS. 9-12 and 15, and FIGS. 22 and 23, the magnet to be detected 900 is arranged in the height direction of the magnetic sensor 100. In an embodiment, the magnet to be detected 900 is arranged at one side of the magnetic sensor 100 in the height direction of the magnetic sensor 100. In the first state, the first sensing assembly 300 is relatively close to the first magnetic pole N, and the second sensing assembly 500 is relatively away from the first magnetic pole N. The first sensing assembly 300 includes a first sensing element group arranged in the first direction X. For example, the first sensing element group includes a sensing element 31 and a sensing element 32. The second sensing assembly 500 includes a second sensing element group arranged in the first direction X. For example, the second sensing element group includes a sensing element 51 and a sensing element 52.

In an embodiment, any of the following signals may be used for calculating the first state data corresponding to the first state of the magnet to be detected 900:
(1) a first intermediate signal op11 formed by performing a first operation op1 on signals formed at the first sensing element group; for example, the first operation op1 being performed on a detection signal of the sensing element 31 and a detection signal of the sensing element 32;
(2) a second intermediate signal op12 formed by performing a first operation op1 on signals formed at the second sensing element group; for example, the first operation op1 being performed on a detection signal of the sensing element 51 and a detection signal of the sensing element 52; and
(3) in the embodiment shown in FIGS. 9-12 and 15, a first output signal o21 formed by performing a second operation op2 on a first intermediate signal op11 and a second intermediate signal op12.

Thus, at least one of the first intermediate signal, the second intermediate signal and the first output signal is used for calculating first state data of the magnet to be detected.

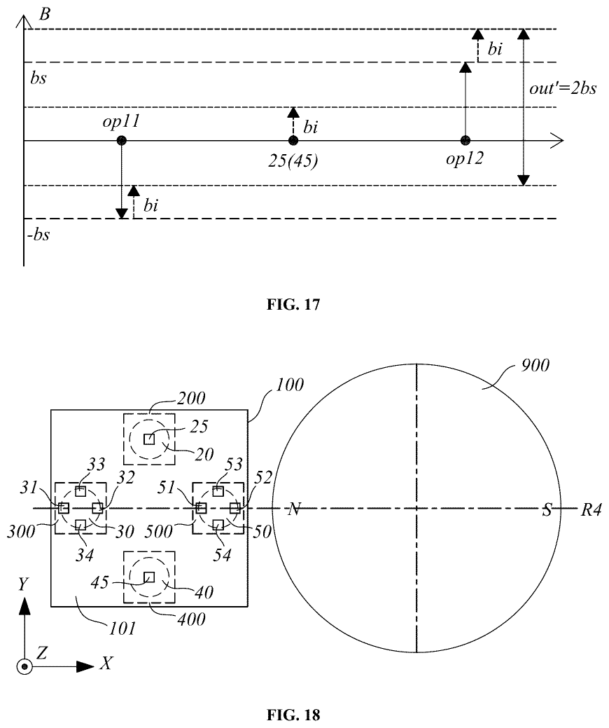

As shown in FIGS. 16 and 17, by defining the third direction Z as a forward direction of the magnetic-field strength, the first intermediate signal op11 is capable of generating reverse magnetic-field strength −bs at the first sensing assembly 300 when no interference is taken into account, and is capable of generating reverse magnetic-field strength (−bs+bi) containing interfering magnetic-field strength +bi when interference is taken into account. The second intermediate signal op12 is capable of generating forward magnetic-field strength +bs at the second sensing assembly 500 when no interference is taken into account, and is capable of generating forward magnetic-field strength (+bs+bi) containing interfering magnetic-field strength +bi when interference is taken into account.

In a case where the interfering magnetic-field strength +bi can be determined by a reference assembly (for example, a first reference assembly 200 in FIG. 9) as described later, the magnetic-field strength at the sensing assembly can be determined only by one set of sensing element and at least one set of reference assembly even when interference is taken into account. However, in a case where the reference assembly is not provided and the interfering magnetic-field strength +bi cannot be directly known, the magnetic-field strength at the sensing assembly can also be retained and the interfering magnetic-field strength can be canceled by performing an operation on the first intermediate signal op11 and the second intermediate signal op12.

The magnetic sensor 100 provided by the present invention can achieve interference shielding only by two sets of components, for example, two sets of the sensing assemblies, so that the manufacturing cost and the energy consumption of the magnetic sensor are greatly reduced.

In an embodiment, the first operation op1 and the second operation op2 are inverse. Thus, eliminating an interfering magnetic field or extracting the strength of the interfering magnetic field can be facilitated.

When the first operation op1 is a differential operation, as previously described, since magnetic-field components that are opposite in the first direction X (as shown in FIG. 11) or magnetic-field components that are opposite in the third direction Z (as shown in FIG. 12) exist at the sensing element 31 and the sensing element 32, this difference between the detection signals of the two sensing elements can be amplified by performing the differential operation on the detection signals of the two sensing elements to offset other magnetic-field components in the same directions for analysis.

If the second operation op2 is a superposition operation, the differences determined at the first sensing assembly 300 and the second sensing assembly 500 can be superimposed and further amplified for analysis; or the difference between the magnetic fields at the two positions can be analyzed conveniently because the magnetic fields at the two assemblies are in opposite directions. The corresponding effects of the above two solutions depend on “minuend” and “subtrahend” in the differential operation on the sensing elements of the two sensing assemblies.

When the first operation op1 is a superposition operation, as previously described, since magnetic-field components that are opposite in the first direction X or in the third direction Z exist at the sensing element 31 and the sensing element 32, the corresponding magnetic field can be eliminated by performing the superposition operation on the detection signals of the two sensing elements.

If the second operation op2 is a differential operation, the actually available detection signals can be superimposed based on the fact that the magnetic field in a sensing direction of the first sensing assembly 300 (for example, the opposite direction of the third direction Z or of its height direction) at the first sensing assembly 300 is opposite to the magnetic field in a sensing direction of the second sensing assembly 500 (for example, the third direction Z or of its height direction) at the second sensing assembly 500, which is convenient for analyzing the current state of the magnet to be detected 900. As shown in FIGS. 16 and 17, by performing the differential operation on the first intermediate signal op11 and the second intermediate signal op12, the first output signal o21 with the magnetic-field strength of out=2bs can be obtained regardless of whether an interfering magnetic field exists or not.

In an embodiment of the present invention, the first operation op11 is a superposition operation and the second operation op2 is a differential operation, which can be equally applicable in other embodiments.

In the process of angular change by movement of the magnet to be detected 900, particularly in the process of rotation of the magnet to be detected 900 around its central axis, all parts at the magnet to be detected 900 other than the central axis move, and there exist movement directions corresponding to the parts. For example, there exists a movement direction (for example, the opposite direction −Y of the second direction) for movement of the part at the magnet to be detected 900 corresponding to the first sensing assembly 300, or there exists a movement direction (for example, the opposite direction −Y of the second direction) for movement of the part at the magnet to be detected 900, to which the first sensing assembly 300 points after being projected onto the magnet to be detected 900. In the first state, the first direction X may be perpendicular to the movement direction, or difference between 90 degree and an angle between the first direction X and the movement direction may be less than a predetermined threshold. In this way, the magnetic sensor 100 can effectively detect the state data, for example, rotational angle, of the magnet to be detected 100.

Further, in the embodiment, the first sensing assembly 300 includes a first magnetic aggregation element 30. The first sensing element group includes at least two sensing elements (such as the sensing element 31 and the sensing element 32) arranged in the first direction X. The first sensing element group includes at least two sensing elements, which may be arranged on two sides of the first magnetic aggregation element 30. The second sensing assembly 500 includes a second magnetic aggregation element 50. The second sensing element group includes at least two sensing elements (such as the sensing element 51 and the sensing element 52) arranged in the first direction X. The second sensing element group includes at least two sensing elements, which may be arranged on two sides of the second magnetic aggregation element 50.

The present invention is not limited thereto. The first sensing assembly 300 may also include two sensing elements (such as the sensing element 33 and the sensing element 32) arranged in the second direction Y, and the two sensing elements may also be located on two sides of the first magnetic aggregation element 30. The second sensing assembly 500 may also include two sensing elements (such as the sensing element 53 and the sensing element 54) arranged in the second direction Y, and the two sensing elements may also be located on two sides of the second magnetic aggregation element 50. The second direction Y is perpendicular to the first direction X. The above two embodiments can be implemented in parallel or concurrently.

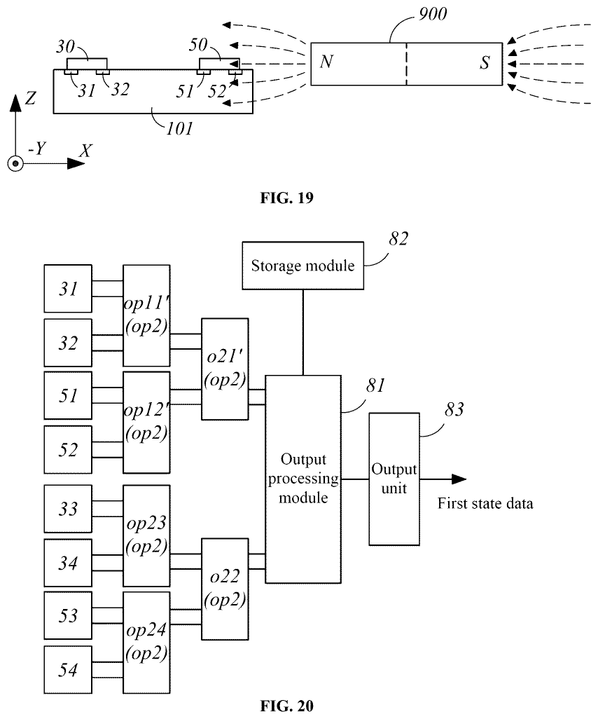

As shown in FIGS. 18, 19 and 24, the magnet to be detected 900 is arranged in the width direction of the magnetic sensor 100. The magnet to be detected 900 is arranged in the first direction X. In the first state, the sensing assembly and the magnet to be detected 900 are aligned in the height direction (which may be the third direction Z) of the magnetic sensor. In an embodiment, the magnet to be detected 900 is arranged at one side of the magnetic sensor 100 in the width direction of the magnetic sensor 100 or in the first direction X. In an embodiment, in the first state, the angle between the arrangement direction of the sensing assembly and the magnet to be detected 900, and the height direction of the magnet sensor is less than a predetermined threshold. For example, in the embodiment shown in FIG. 19, the magnetic sensor 100 and the magnet to be detected 900 may be aligned in the third direction Z by means of the magnetic aggregation element. In this way, the magnetic aggregation in the third direction Z can be made more uniform.

As shown in FIGS. 18-20 and FIGS. 24 and 25, the magnet to be detected 900 is arranged in the width direction of the magnetic sensor 100. In an embodiment, the magnet to be detected 900 is arranged at one side in the width direction of the magnetic sensor 100. In the first state, the first sensing assembly 300 is relatively away from the first magnetic pole N. and the second sensing assembly 500 is relatively close to the first magnetic pole N. The first sensing assembly 300 includes a first sensing element group arranged in the first direction X. For example, the first sensing element group includes a sensing element 31 and a sensing element 32. The second sensing assembly 500 includes a second sensing element group arranged in the first direction X. For example, the second sensing element group includes a sensing element 51 and a sensing element 52.

In an embodiment, any of the following signals may be used for calculating the first state data corresponding to the first state of the magnet to be detected 900:
(1) another first intermediate signal op11′ formed by performing a second operation op2 on signals formed at the first sensing element group; for example, the second operation op2 being performed on a detection signal of the sensing element 31 and a detection signal of the sensing element 32;
(2) another second intermediate signal op12′ formed by performing a first operation op1 on signals formed at the second sensing element group; for example, the second operation op2 being performed on a detection signal of the sensing element 51 and a detection signal of the sensing element 52; and
(3) another first output signal o21′ formed by performing a second operation op2 on a first intermediate signal op11′ and a second intermediate signal op12′.

Thus, at least one of the first intermediate signal, the second intermediate signal and the first output signal is used for calculating first state data of the magnet to be detected.

In one aspect, since the magnet to be detected 900 is arranged in the width direction of the magnetic sensor 100, the direction of the magnetic field at the sensing assembly is mainly in the first direction X and its opposite direction, and a magnetic-field component for example in the third direction Z (or the height direction of the magnetic sensor 100) may be generated. Due to the existence of the magnetic aggregation element, magnetic-field deflection for example near the sensing element 31 in FIG. 12 may be formed at the first sensing assembly 300 and the second sensing assembly 500. However, since the two sensing elements arranged in the first sensing assembly 300 in the first direction X are both away from the first magnetic pole N. and the two sensing elements arranged in the second sensing assembly 500 in the second direction Y are both close to the first magnetic pole N, even if deflection occurs, the two sensing elements in each sensing assembly are not much different in magnetic-field component in the third direction Z, thereby helping to eliminate or extract the magnetic-field component at a single sensing assembly.

In another aspect, since the second sensing assembly 500 is closer to the first magnetic pole N, the total output formed by the two sensing assemblies is different based on the distribution principle of the magnetic field. Therefore, not only can the current state of attitude of the magnet to be detected 900 be judged, but also the current state of movement of the magnet to be detected 900 can be calculated based on the difference of the total output.

Thus, the magnetic sensor 100 provided by the present invention can detect the state of movement only by two sets of sensing assemblies, so that the manufacturing cost and the energy consumption of the magnetic sensor can be greatly reduced.

In an embodiment, the second operation op2 is a differential operation. In this way, the magnetic-field component in a specific direction can be eliminated, and the state of the magnet to be detected 900 can be determined according to the difference between the two sensing assemblies.

In the process of angular change by movement of the magnet to be detected 900, particularly in the process of rotation of the magnet to be detected 900 around its central axis, all parts at the magnet to be detected 900 other than the central axis move, and there exist movement directions corresponding to the parts. For example, there exists a movement direction (for example, the opposite direction −Y of the second direction) for movement of the part at the magnet to be detected 900 corresponding to the second sensing assembly 500, or there exists a movement direction (for example, the opposite direction −Y of the second direction) for movement of the part at the magnet to be detected 900, which is closest to the second sensing component 500. In the first state, the first direction X may be perpendicular to the movement direction, or difference between 90 degree and an angle between the first direction X and the movement direction may be less than a predetermined threshold. In this way, the magnetic sensor 100 can effectively detect the state data, for example, rotational angle, of the magnet to be detected 100.

Further, in the embodiment, the first sensing assembly 300 includes a first magnetic aggregation element 30. The first sensing element group includes at least two sensing elements (such as the sensing element 31 and the sensing element 32) arranged in the first direction X. The first sensing element group includes at least two sensing elements, which may be arranged on two sides of the first magnetic aggregation element 30. The second sensing assembly 500 includes a second magnetic aggregation element 50. The second sensing element group includes at least two sensing elements (such as the sensing element 51 and the sensing element 52) arranged in the first direction X. The second sensing element group includes at least two sensing elements, which may be arranged on two sides of the second magnetic aggregation element 50.

As shown in FIGS. 18-20, FIGS. 24 and 25 in combination with FIGS. 4-7, 9 and 22, in the first state, the first sensing assembly 300 further includes a third sensing element group arranged in the second direction Y. For example, the third sensing element group includes a sensing element 33 and a sensing element 34. The second sensing assembly further includes a fourth sensing element group arranged in the second direction Y. For example, the fourth sensing element group includes a sensing element 53 and a sensing element 54.

In an embodiment, any of the following signals may be used for calculating the first state data corresponding to the first state of the magnet to be detected 900:
(1) a third intermediate signal op23 formed by performing a second operation op2 on signals formed at the third sensing element group; for example, the second operation op2 being performed on a detection signal of the sensing element 33 and a detection signal of the sensing element 34;
(2) a fourth intermediate signal op24 formed by performing a second operation op2 on signals formed at the fourth sensing element group; for example, the second operation op2 being performed on a detection signal of the sensing element 53 and a detection signal of the sensing element 54; and
(3) a second output signal o22 formed by performing the second operation op2 on a third intermediate signal op23 and a fourth intermediate signal op24.

Thus, at least one of the third intermediate signal, the fourth intermediate signal and the second output signal is used for calculating first state data of the magnet to be detected.

Since the third sensing element group and the fourth sensing element group are arranged in a different direction from that of the first sensing element group and the second sensing element group, the sensitivity of the first sensing assembly in another aspect can be provided.

In an embodiment, the second operation is a differential operation. The first sensing element group is arranged in the second direction Y. and the second sensing element group is arranged in the second direction Y. In a case where the second direction Y is perpendicular to the first direction X, for the directions of the magnetic fields at the sensing elements 33 and 34, a reference may be made to the direction of the magnetic field at the sensing element 31 in FIG. 12. A plane parallel to the first direction X and the third direction Z is made across the center of the magnet to be detected 900. If the sensing element 33 and the sensing element 34 are symmetrical with respect to the plane, in the first state, the distribution of magnetic fields at the sensing elements 33 and 34 are the same. When the magnet to be detected 900 starts to rotate from the first state, the sensing element 33 and the sensing element 34 can sensitively determine, from the difference in distribution of magnetic field between the sensing element 33 and the sensing element 34, the magnitude of change in the state of the magnet to be detected 900.

In an embodiment, the first direction X is perpendicular to a movement direction of a part (particularly the part close to the sensing element 51 and the sensing element 52 in the second sensing assembly 500) at the magnet to be detected 900 corresponding to the sensing element, or difference between 90 degree and an angle between the first direction X and the movement direction is less than a predetermined threshold. The second direction Y is same as the movement direction of the part, or difference between the two is less than a predetermined threshold. In this way, the movement of the magnet to be detected 900 can be detected more sensitively.

Further, in the embodiment, the first sensing assembly 300 includes a first magnetic aggregation element 30. The first sensing element group includes at least two sensing elements (such as the sensing element 31 and the sensing element 32) arranged in the first direction X. The first sensing element includes at least two sensing elements, which may be arranged on two sides of the first magnetic aggregation element 30. The third sensing element group includes at least two sensing elements (such as the sensing element 33 and the sensing element 34) arranged in the second direction Y. The third sensing element group includes at least two sensing elements, which may be arranged on two sides of the first magnetic aggregation element 30.

The second sensing assembly 500 includes a second magnetic aggregation element 50. The second sensing element group includes at least two sensing elements (such as the sensing element 51 and the sensing element 52) arranged in the first direction X, and the two sensing elements may also be arranged on two sides of the second magnetic aggregation element 50. The fourth sensing element group includes at least two sensing elements (such as the sensing element 53 and the sensing element 54) arranged in the second direction Y, and the two sensing elements may also be arranged on two sides of the second magnetic aggregation element 50.

In a case where the magnet to be detected 900 is arranged in the height direction of the magnetic sensor 100 (specifically, in an embodiment, arranged at one side in the height direction of the magnetic sensor 100), as previously described, the third sensing element group and the fourth sensing element group may also be provided, so as to enable the first sensing assembly 300 and the second sensing assembly 500 to obtain sensitivities in more directions.

In the technical solutions provided by the present invention, sensing elements, particularly a plurality of sensing elements arranged in a same sensing assembly, may be configured to be of a same structure, thereby ensuring uniform detection of magnetic fields in all directions. In the technical solutions provided by the present invention, sensing assemblies, particularly a plurality of sensing assemblies arranged in a same magnetic sensor 100, may be configured to be of a same structure, thereby ensuring uniform detection of magnetic fields at various positions. The above two embodiments can be implemented in the same solution or may be implemented in different solutions in parallel.

With reference to FIGS. 4-7, in an embodiment, a sensing element is configured to at least partially overlaps an extension surface of a corresponding magnetic aggregation element. In an embodiment, a projection of a sensing element at a corresponding magnetic aggregation element at least partially overlaps an extension surface of a corresponding magnetic aggregation element. For example, in the embodiment of FIGS. 4 and 5, the projection of the sensing element 33 at the first magnetic aggregation element 30 partially overlaps the extension surface on a side of the first magnetic aggregation element 30 close to the base plate 101. In an example, the projection of the sensing element 33 at the first magnetic aggregation element 30 is smaller than an area of a side surface of the sensing element 33 close to the first magnetic aggregation element 30. In other embodiments, the projection of the sensing element at the first magnetic aggregation element 30 may be equal to the area of the side surface of the sensing element 33 close to the first magnetic aggregation element 30 (for example, the sensing element 35 in FIG. 7). In the embodiment, the sensing element 34 may be of a same configuration as described above with respect to the first magnetic aggregation element 30. In an embodiment provided in FIGS. 6 and 7, the sensing element 31 and the sensing element 32 may have the configuration as described above.

As shown in FIGS. 3-9, 13, 14, 18, 21, 22 and 24, in an embodiment, the magnetic sensor 100 may also include a reference assembly. In order to simplify the expression, a first reference assembly 200 will be mainly described below to define the reference assembly provided by the present invention. The definition of the reference assembly does not imply that the devices therein are necessarily packaged as a whole. In an embodiment where no integral package occurs, the following descriptions of the reference assembly can be interpreted as descriptions of an area in the magnetic sensor 100 for providing the devices contained in the reference assembly. The reference assembly is interpreted as an area at the magnetic sensor 100 for providing reference.

The reference assembly includes a magnetic aggregation element and a reference element adjacent to an extension surface of the magnetic aggregation element. The number of the reference element may be one or more. For example, a first reference assembly 200 includes a third magnetic aggregation element 20, and a reference element, for example, a reference element 25. The reference element 25 is adjacent to one extension surface of the third magnetic aggregation element 20. In an embodiment, a magnetic field of the magnet to be detected 900 near the extension surface is deflected in the direction of the extension surface due to a magnetic aggregation function of the third magnetic aggregation element 20.

The third magnetic aggregation element 20 may be of a same configuration as the first magnetic aggregation element 30 and the second magnetic aggregation element 50, or may be configured differently.

At least one reference assembly is arranged on a carrying surface of the base plate 101. At least the first reference assembly 200 is arranged on the carrying surface of the base plate 101. In other embodiments, a second reference assembly 400 may also be arranged on the carrying surface of the base plate 101. In addition, the carrying surface for providing the reference assembly and the carrying surface for providing the sensing assembly may be the same, and in some embodiments, may also be different, and a similar effect can be achieved by adjusting a subsequent operation process.

A center of at least one reference element is configured to be at a position corresponding to an axis of symmetry of the extension surface of the magnetic aggregation element. In an embodiment, a projection of a center of at least one reference element onto the extension surface of the corresponding magnetic aggregation element is located at an axis of symmetry of the extension surface of the magnetic aggregation element. For example, in FIG. 7 or 8, the projection of the center of the reference element 25 onto the extension surface of the third magnetic aggregation element 20 is located at the axis of symmetry of the extension surface of the third magnetic aggregation element 20. In this way, based on the fact that most of the magnetic-field components at the reference assembly cancel each other out due to a magnetic aggregation function, but the property of including an external uniform interfering magnetic field is always retained, the current situation of the interfering magnetic field can be known by using the reference assembly for analysis or targeted elimination in a signal output by the sensing assembly.

Referring to FIG. 13, in the first state, the magnetic-field components in the third direction Z and its opposite direction are concentrated on a side of the third magnetic aggregation element 20 close to the magnet to be detected 900 due to the existence of the third magnetic aggregation element 20, and diverged on the side of the extension surface of the third magnetic aggregation element 20. Although the third magnetic aggregation element 20 causes the magnetic-field components in the third direction Z and its opposite direction to deflect in the first direction X or its opposite direction, the magnetic field at the reference element 25 is always kept in the third direction Z and its opposite direction based on the relative position of the third magnetic aggregation element 20 with respect to the reference element 25. In a case where the magnetic-field components in the third direction Z change under the influence of the magnet to be detected 900, the reference element 25 may also generate a relatively single detection signal to correspond to a composite detection signal generated by the sensing element. In a case where the magnetic-field component in the third direction Z remains unchanged during changes in states of the magnet to be detected 900, the magnetic field in the third direction Z is only affected by an external interfering magnetic field, thus facilitating elimination of the influence of the interfering magnetic field from the detection signal of the sensing element.

In an embodiment, the sensing assembly and the reference assembly may be configured to be of a same structure or of similar structures, thus ensuring that signals output by the two assemblies can form an accurate contrast.

In the solution provided by FIGS. 4 and 5, the first reference assembly 200 may include a reference element 23 and a reference element 24, and projections of their centers onto the extension surface of the second magnetic aggregation element 20 may be located on an axis of symmetry (e.g., extending in the second direction Y) of the extension surface of the third magnetic aggregation element 20. The axis of symmetry may also be replaced with a plane, which is made across a center of the third magnetic aggregation element 20 and is parallel to the second direction Y and the third direction Z. The third magnetic aggregation element 20 may further include another axis of symmetry (e.g., extending in the first direction X) perpendicular to the axis of symmetry, or another plane, which is made across a center of the third magnetic aggregation element and is parallel to a YZ plane, and the reference element 23 and the reference element 24 may be symmetrical with respect to the axis of symmetry or the plane. Similarly, the first sensing assembly 300 may also include a sensing element 33 and a sensing element 34 corresponding to the reference element 23 and the reference element 24 respectively.

In the solution provided in FIG. 6, a reference element 21 and/or a reference element 22 may be defined as the reference element whose center is located at the axis of symmetry of the extension surface of the third magnetic aggregation element 20. A reference element 23 and/or a reference element 24 may be defined as the reference element described above. The first sensing assembly 300 may also include the sensing element 31, the sensing element 32, the sensing element 33 and the sensing element 34 corresponding to the reference element 21, the reference element 22, the reference element 23 and the reference element 24 respectively.

In the solution provided in FIG. 7, the reference element 21 and/or the reference element 25 and/or the reference element 22 may be defined as the reference element whose center is located at an axis of symmetry of an extension surface of the third magnetic aggregation element 20. The reference element 23 and/or the reference element 25 and/or the reference element 24 may be defined as the reference element described above. The first sensing assembly 300 may include the sensing element 31, the sensing element 32, the sensing element 33, the sensing element 34 and the sensing element 35 corresponding to the reference element 21, the reference element 22, the reference element 23, the reference element 24 and the reference element 25 respectively.

The reference element is arranged between a corresponding magnetic aggregation element and the base plate. For example, in FIGS. 4 and 5, the reference element 24 is located between the third magnetic aggregation element 20 and the base plate 101, and the reference element 23 is located between the third magnetic aggregation element 20 and the base plate 101. In this way, the adjustment of magnetic-field deflection of the magnetic aggregation element can be fully accepted.

As shown in FIGS. 1, 9 and 10, the magnet to be detected 900 is arranged in the height direction of the magnetic sensor 100. The magnet to be detected 900 is arranged in the third direction Z. In the first state, the axis of symmetry of the extension surface of the magnetic aggregation element of the reference assembly is located at a plane where the magnetic pole interface of the magnet to be detected 900 is located. In an embodiment, the magnet to be detected 900 is arranged at one side in the height direction of the magnetic sensor 100 or in the third direction Z. For example, in FIGS. 9 and 10, in the first state, an axis of symmetry of the extension surface of the third magnetic aggregation element 20 of the first reference assembly 200 is located at a plane where the magnetic pole interface of the magnet to be detected 900 is located. In the first state, an axis of symmetry of the extension surface of the fourth magnetic aggregation element 40 of the second reference assembly 400 is located at a plane where the magnetic pole interface of the magnet to be detected 900 is located.

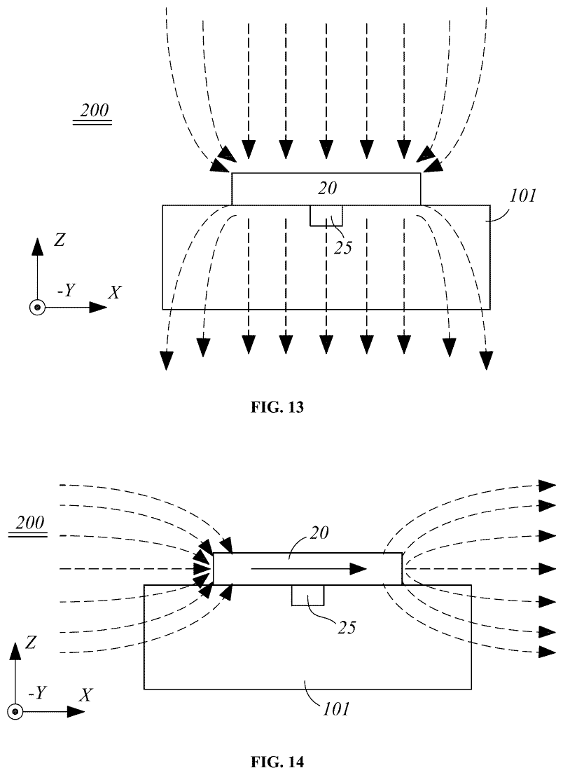

As shown in FIG. 14, in the first state, the magnetic-field components in the first direction X and its opposite direction are all in the first direction X on two sides of the first reference assembly 200 close to the first magnetic pole N and away from the first magnetic pole N, and due to the existence of the third magnetic aggregation element 20, the magnetic-field components in this direction do not pass through the reference element 25 and form a “magnetic-field vacuum zone”, thus achieving the effect of shielding the magnetic-field interference in a non-sensing direction.

As shown in FIGS. 16 and 17, when an axis of symmetry of the extension surface of the third magnetic aggregation assembly 20 is located at a plane where the magnetic pole interface of the magnet to be detected 900 is located, the magnetic-field component of the first reference assembly 200 arranged longitudinally close to the first magnetic pole N is in the opposite direction of the third direction Z, and the magnetic-field component of the first reference assembly 200 arranged longitudinally away from the first magnetic pole N (e.g., close to a second magnetic pole S) is in the third direction Z. In this way, the longitudinally arranged magnetic-field components are internally canceled at the first reference assembly 200, so that the detection signals of the reference element 25 and a reference element 45 in the second reference assembly 400 are zero.

When an external interfering signal appears, outputs of the detection signals of the reference element 25 and the reference element 45 are superimposed, and the interfering magnetic-field strength +bi is directly presented, so that the external interfering signal may be directly known from the reference assembly and can be further analyzed or eliminated.

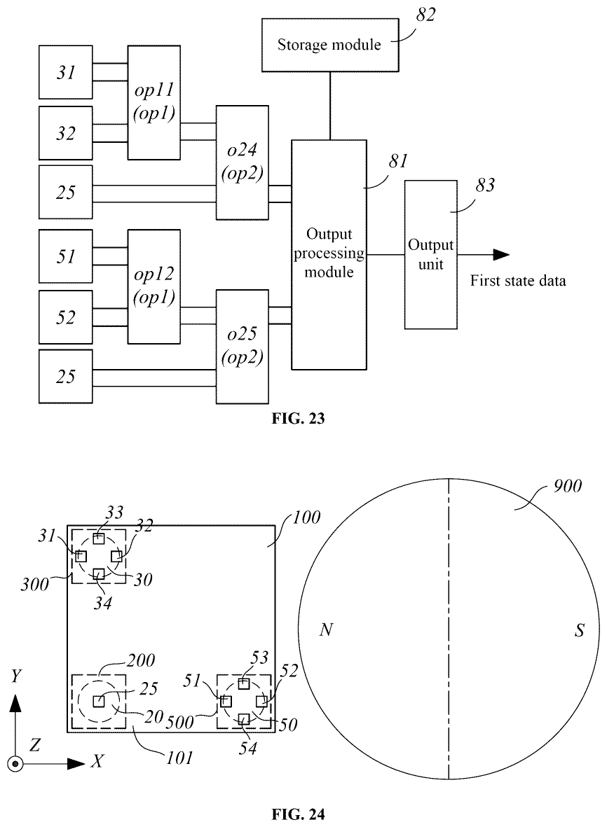

In an embodiment shown in FIGS. 22 and 23, the reference assembly may have no above-mentioned positional relationship with the magnet to be detected 900, because the “magnetic-field vacuum zone” built causes the reference assembly to only output the magnetic-field detection signal in the third direction Z or its opposite direction, which may also be used as a reference for the sensing assembly in response to an external interfering magnetic field.

As shown in FIGS. 9-15, the magnet to be detected 900 is arranged in the height direction of the magnetic sensor 100. In an embodiment, the magnet to be detected 900 is arranged at one side in the height direction of the magnetic sensor 100. In the first state, the first reference assembly 200 includes a first reference element 25, and a center of the first reference element 25 is located on the plane where the magnetic pole interface of the magnet to be detected 900 is located; and the second reference assembly 400 includes a second reference element 45, and a center of the second reference element 45 is located on the plane where the magnetic pole interface of the magnet to be detected 900 is located.

In an embodiment, the first reference element 25 and the second reference element 45 are arranged at different positions of the base plate, thus forming a contrast with each other and forming sensitivity in more directions.

In an embodiment, any of the following signals may be used for calculating the first state data corresponding to the first state of the magnet to be detected 900:
(1) a fifth intermediate signal (denoted by the reference sign of the first reference element 25 in FIGS. 16 and 17) formed at the first reference element 25;
(2) a sixth intermediate signal (denoted by the reference sign of the second reference element 45 in FIGS. 16 and 17) formed at the second reference element 45; and
(3) a third output signal o23 formed by performing a second operation op2 on a fifth intermediate signal and a sixth intermediate signal.

Thus, at least one of the fifth intermediate signal, the sixth intermediate signal and the third output signal is used for calculating first state data of the magnet to be detected.

In the first state shown in FIGS. 9-17, the magnetic-field strength indicated by the fifth intermediate signal and the sixth intermediate signal is the same, which is 0 or interfering magnetic-field strength +bi. When the second operation op2 is a superposition operation, the value of the interfering magnetic-field strength can be amplified; and when the second operation op2 is a differential operation, the interfering magnetic field can be canceled.

When the magnet to be detected 900 rotates clockwise, the direction of the magnetic field at the first reference element 25 is in an opposite direction to the third direction Z, and a direction of the magnetic field at the second reference element 45 is in the third direction Z. At this time, the fifth intermediate signal and the sixth intermediate signal indicate the magnetic fields of the same strength but in opposite directions, and carry interfering magnetic fields in a same direction. For example, one of the values of the magnetic field strength corresponding to the fifth intermediate signal and the sixth intermediate signal is (+bs+bi), and the other of the values of the magnetic field strength corresponding to the fifth intermediate signal an the sixth intermediate signal is (−bs+bi). If the second operation op2 is a differential operation, the detection signal indicating the current state of the magnet to be detected 900 can be amplified. If the second operation op2 is a superposition operation, the interfering magnetic field can be amplified for subsequent analysis.

As shown in FIGS. 22 and 23, the magnet to be detected 900 is arranged in the height direction of the magnetic sensor 100. In an embodiment, the magnet to be detected 900 is arranged at one side of the magnetic sensor 100 in the height direction of the magnetic sensor 100. A reference element is arranged on the base plate 101. For example, in the FIGS. 22 and 23, there may be only one reference element 25 on the base plate 101, but no other reference elements or reference assemblies.

In the first state, the first sensing assembly 300 is relatively close to the first magnetic pole N. and includes a first sensing element group arranged in the first direction X. For example, the first sensing element group includes a sensing element 31 and a sensing element 32. The second sensing assembly 500 is relatively away from the first magnetic pole N and includes a second sensing element group arranged in the first direction X. For example, the second sensing element group includes a sensing element 51 and a sensing element 52.

In an embodiment, any of the following signals may be used for calculating the first state data corresponding to the first state of the magnet to be detected 900:
(1) a first intermediate signal op11 formed by performing a first operation op1 on signals formed at the first sensing element group; for example, the first operation op1 being performed on a detection signal of the sensing element 31 and a detection signal of the sensing element 32;
(2) a second intermediate signal op12 formed by performing a first operation op1 on signals formed at the second sensing element group; for example, the first operation op1 being performed on a detection signal of the sensing element 51 and a detection signal of the sensing element 52;
(3) a seventh intermediate signal formed at the reference element; for example, a seventh intermediate signal formed at the first reference element 25;
(4) a fourth output signal o24 formed by performing a second operation op2 on a first intermediate signal op11 and a seventh intermediate signal; and
(5) a fifth output signal o25 formed by performing the second operation op2 on a second intermediate signal op12 and a seventh intermediate signal.

Thus, at least one of the first intermediate signal, the second intermediate signal, the seventh intermediate signal, the fourth output signal and the fifth output signal is used for calculating first state data of the magnet to be detected.

In the process of generating the fourth output signal o24 and the fifth output signal o25, characteristics of a single direction (e.g., the third direction Z or its opposite direction) of the magnetic field can be detected using the first reference element 25 to eliminate the influence of at least part of the interfering magnetic field.

In addition, as shown in FIG. 22, in the first state, the first sensing assembly 300 is relatively close to the first magnetic pole N.

The first sensing assembly 300 is at a first relative distance away from the first magnetic pole N. The reference assembly (for example, the first reference assembly 200) is at a second relative distance away from the first magnetic pole N. In an embodiment, the second relative distance is equal to or greater than the first relative distance. In an embodiment, difference between the second relative distance and the first relative distance is less than a predetermined threshold. In this way, it is possible to avoid changing the positivity or negativity of the value of the magnetic field strength carried by the detection signal when the interfering magnetic field is subsequently canceled.

The first relative distance may an average distance between a center of the sensing assembly and points on the first magnetic pole N. The first relative distance may be an average distance between a center of the reference assembly and points on the first magnetic pole N. In other embodiments, any other distance that can roughly indicate the relative proximity can also be used as the first relative distance or the second relative distance.

The first relative distance may be interpreted as a relative distance between any sensing element closer to the first magnetic pole N and the first magnetic pole N. As shown in FIG. 22, although the first sensing assembly 300 is closer to the first magnetic pole N at this time, the second sensing assembly 500 is changed to “the sensing assembly closer to the first magnetic pole N” after the magnet to be detected 900 rotates by 180 degrees. At this time, the first relative distance refers to a distance between the second sensing assembly 500 and the first magnetic pole N. In the first state shown in FIG. 24, the sensing assembly closer to the first magnetic pole N is the second sensing assembly 500, so the first relative distance refers to the distance between the second sensing assembly 500 and the first magnetic pole N.

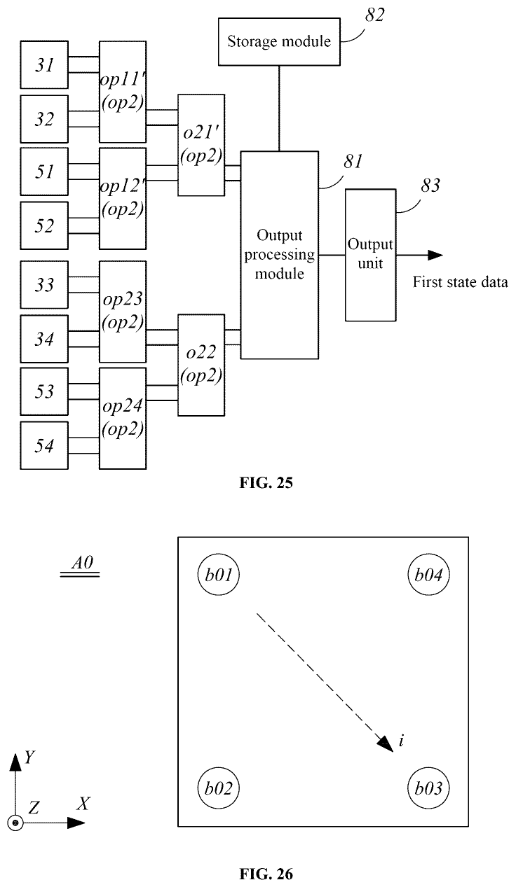

In the embodiment shown in FIGS. 18-20 and the embodiment shown in FIGS. 24 and 25, the above-mentioned reference assemblies may also be provided correspondingly, which will not be repeated herein. In the embodiment shown in FIGS. 18-20, the relative positional relationship between the reference assembly, the sensing assembly and the magnetic sensor 100 may be configured with reference to the embodiment shown in FIGS. 9-17. In the embodiment shown in FIGS. 24 and 25, the relative positional relationship between the reference assembly, the sensing assembly and the magnetic sensor 100 may be configured with reference to the embodiment shown in FIGS. 22 and 23.

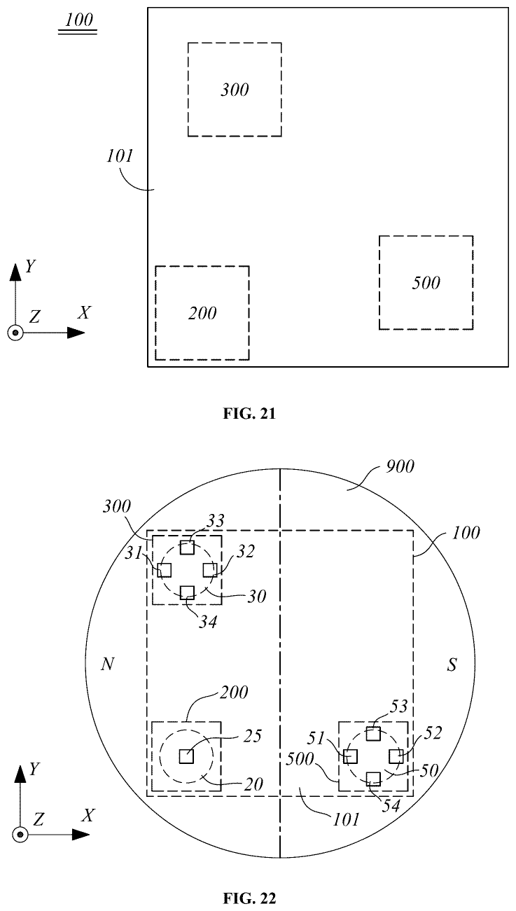

As shown in FIGS. 3 and 21, position of the reference assembly and/or the sensing assembly on the base plate 101 is not necessarily limited in the present invention, and the accompanying drawings and corresponding textual descriptions are only intended to provide an embodiment or an example of the present invention. When the total number M of the reference assemblies and the sensing assemblies included in the magnetic sensor 100 is greater than or equal to 3, a requirement is to configure the above assemblies as “all center points being not always collinear”. For example, in FIG. 3, the centers of the first reference assembly 200, the first sensing assembly 300, the second reference assembly 400 and the second sensing assembly 500 are not always collinear, and points of the four centers may be connected in sequence to form a quadrilateral. For example, in FIG. 21, the centers of the first reference assembly 200, the first sensing assembly 300 and the second sensing assembly 500 are not always collinear, and points of the three centers may be connected in sequence to form a triangle.

In an embodiment, the reference elements, particularly the reference elements arranged in a same reference assembly, may be configured to be of a same structure. In an embodiment, the reference assemblies, particularly the plurality of reference assemblies arranged in a same magnetic sensor 100, may be configured to be of a same structure. In an embodiment, the sensing element and the reference element, particularly the sensing element and the reference element arranged in a same magnetic sensor 100, may be configured to be of a same structure. In an embodiment, the sensing assembly and the reference assembly, particularly the sensing assembly and the reference assembly arranged in a same magnetic sensor 100, may be configured to be of a same structure. The above four embodiments can be implemented in a same solution or be implemented in different solutions in parallel.

In an embodiment, the reference element is configured to at least partially overlap an extension surface of a corresponding magnetic aggregation element. In an example, a projection of the reference element at the corresponding magnetic aggregation element at least partially overlaps an extension surface of a corresponding magnetic aggregation element. For an embodiment provided in FIG. 8, an area of a projection of the reference element 25 at the third magnetic aggregation element 20 is equal to an area of a side surface of the reference element 25 close to the third magnetic aggregation element 20.

In an embodiment, the sensing direction of the sensing element is perpendicular to an extension surface of a corresponding magnetic aggregation element. Taking FIG. 6 as an example, the sensing direction of the sensing element 31 is perpendicular to the first magnetic aggregation element 30. The sensing direction of the reference element is perpendicular to the extension surface of the corresponding magnetic aggregation element. Taking FIG. 8 as an example, the sensing direction of the reference element 25 is perpendicular to the third magnetic aggregation element 20.

In an embodiment provided by the present invention, for example, an embodiment shown in FIG. 29, a single reference assembly or a single reference element may include a plurality of reference elements or sensing elements with different sensing directions. In an embodiment, the first reference assembly 200 includes a sensing element Ax taking the first direction X as a sensing direction, a sensing element Ay taking the second direction Y as a sensing direction, and/or a sensing element Az taking the third direction Z as a sensing direction. In an embodiment, the first sensing assembly 300 includes a sensing element Ax taking the first direction X as a sensing direction, a sensing element Ay taking the second direction Y as a sensing direction, and/or a sensing element Az taking the third direction Z as a sensing direction.

In the present invention, the first direction X, the second direction Y and the third direction Z are perpendicular to one another.

In an embodiment, any one of the above-mentioned sensing elements or reference elements may include at least one Hall unit. In an embodiment, any one of the above-mentioned sensing elements or reference elements can follow the Hall effect for detection of the magnetic field. In an embodiment, the sensing element comprises at least one Hall unit.

As shown in FIGS. 26-28, current i is introduced at a Hall unit. When a magnetic field is applied to the Hall unit, charges in the current are deflected by the Lorentz force, thus moving towards one electrode and away from another electrode. The electrodes, towards which charges are moving, may be defined as charge deflecting electrodes, and the electrodes, away from which charges are moving, may be defined as charge repelling electrodes.

For example, in FIG. 26, if current i is introduced from an electrode b01 to an electrode b03 of a Hall unit A0, an electrode b04 may be defined as a charge deflecting electrode and an electrode b02 may be defined as a charge repelling electrode. Charge-based accumulation is related to the strength of the magnetic field applied to the Hall unit A0, so that at this time, the electrode b04 and the electrode b02 can form an output carrying a magnetic field-related detection signal.

A charge deflecting electrode at the Hall unit (e.g., the electrode b04 at the Hall unit A0) is configured to form a first Hall output. A charge repelling electrode (e.g., the electrode b02 at the Hall unit A0) is configured to form a second Hall output. The sensing assembly takes the first Hall output and the second Hall output as signal outputs of the corresponding sensing element. In a case where a plurality of sensing elements are included in a single sensing assembly, the outputs of a plurality of Hall units, together, serve as the output of the corresponding sensing assembly.

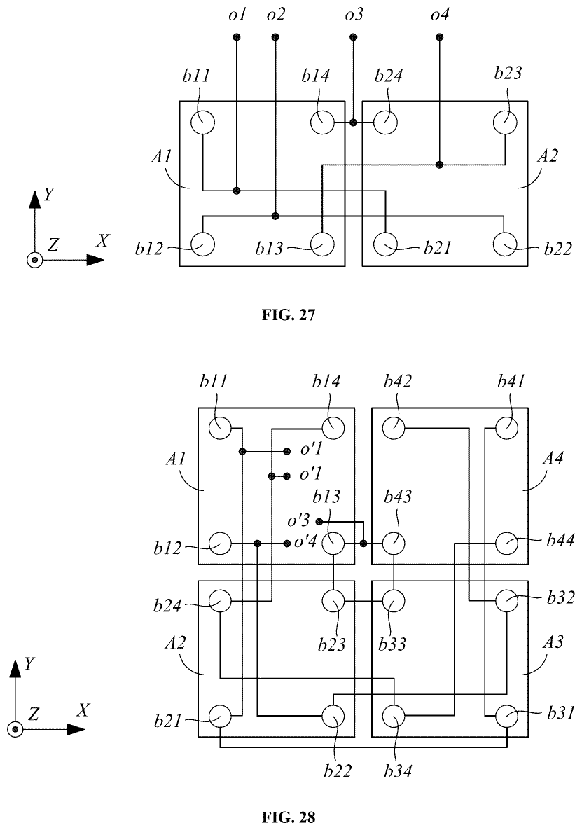

As shown in FIG. 27, a single sensing element may include two Hall units (fe.g., a first Hall unit A1 and a second Hall unit A2). At the Hall units, charge deflecting electrodes (e.g., an electrode b14 and an electrode b24) are coupled to each other, charge repelling electrodes (e.g., an electrode b12 and an electrode b22) are coupled to each other, power supply electrodes (e.g., an electrode b11 and an electrode b21) are coupled to each other, and reference electrodes (e.g., an electrode b13 and an electrode b23 for grounding) are coupled to each other.

As shown in FIG. 28, a single sensing element may include four Hall units (e.g., a first Hall unit A1, a second Hall unit A2, a third Hall unit A3 and a fourth Hall unit A4). At the Hall units, charge deflecting electrodes (e.g., an electrode b14, an electrode b24, an electrode b34 and an electrode b44) are coupled to one another, charge repelling electrodes (e.g., an electrode b12, an electrode b22, an electrode b32 and an electrode b42) are coupled to one another, power supply electrodes (e.g., an electrode b11, an electrode b21, an electrode b31 and an electrode b41) are coupled to one another, and reference electrodes (e.g., an electrode b13, an electrode b23, an electrode b33 and an electrode b23 for grounding) are coupled to one another.

Although not described in the present invention in an expanded manner, the magnetic sensor 100 of any of the embodiments provided above is provided with a corresponding state detection apparatus. As shown in FIGS. 15, 20, 23, and 25, an output processing module 81 is coupled to a respective reference element and reference assembly, and/or a respective sensing element and sensing assembly, for generating an output signal.

Differences between several embodiments provided by the present invention will be reiterated below with reference to accompanying drawings. Understandably, the following differences do not necessarily exist, nor do they necessarily coexist.

FIG. 1 and FIG. 2 respectively illustrate two configurations of positional relationships between the magnet to be detected 900 and the magnetic sensor 100.

FIGS. 9-14, and 22 illustrate two configurations corresponding to the positional relationships of FIG. 1. In the two configurations, the sensing assemblies are similar in number but different in position at which the sensing assembly is disposed, and the reference assemblies are different in both number and position.

FIGS. 18, 19 and 24 illustrate two configurations corresponding to the positional relationships of FIG. 2. In the two configurations, the sensing assemblies are similar in number but different in position at which the sensing assembly is disposed, and the reference assemblies are different in both number and position.

The two solutions shown in FIGS. 9-14, and FIGS. 18 and 19 are similar in configuration with respect to arrangement of assemblies and elements in the magnetic sensor 100, and similar to the corresponding solution in FIG. 3 with respect to the configuration of the number of sensing assemblies and reference assemblies. The two solutions shown in FIG. 22 and FIG. 24 are similar in configuration with respect to arrangement of assemblies and elements in the magnetic sensor 100, and similar to the corresponding solution in FIG. 21 with respect to the configuration of the number of sensing assemblies and reference assemblies.

FIGS. 4-7 provide three configuration solutions of the sensing assembly, and FIGS. 4-8 provide four configuration solutions of the reference assembly. The main difference between the above configuration solutions lies in the number of assemblies and their arrangement positions on the base plate 101. In addition, in some embodiments, the sensing assembly may also be interpreted as a kind of reference assembly, specifically as a reference assembly for detecting state data of the magnet to be detected.

FIGS. 15, 20, 23 and 25 provide four state detection apparatuses, which respectively correspond to the four embodiments provided in FIGS. 9, 18, 22 and 24. All of the state detection apparatuses can obtain, through operations, signals directly carrying state information of the magnet to be detected 900, or can directly output corresponding state dat. Based on the excellence of the magnetic sensor 100, the state detection apparatuses have strong anti-interference performance and universal applicability.

FIGS. 25-29 provide a plurality of configuration solutions of the sensing elements and the reference elements, where the solutions provided in FIGS. 25-28 lie in configuration of the Hall units. The configuration of the Hall units includes an internal connection relationship and circuit composition of the sensing elements or the reference elements. The solution provided in FIG. 29 lies in provision of multi-directionally-sensitive sensing elements or reference elements, providing a holistic architecture for the sensing direction so as to realize extended configuration of the sensing elements or reference elements.

the differences between the embodiments of the present invention are not limited thereto, and similar or different embodiments can also be explained with respect to each other. The embodiments having similarities to each other are not necessarily the same, and contents such as the number and arrangement positions of assemblies can be expanded according to the inventive concept and technical spirit of the corresponding embodiments.

An embodiment of the present invention also provides a state detection method, which may be applied to the magnetic sensor in any of the above technical solutions, and/or may also be applied to the state detection apparatus corresponding to the magnetic sensor.

As shown in FIG. 29, the state detection method includes the following steps.

Step S1, receiving a first intermediate signal and a second intermediate signal.

As shown in FIGS. 9-15, 18-20, 22 and 23, or FIGS. 24 and 25, the first intermediate signal is formed at a first sensing element group arranged in the first sensing assembly 300 in a first direction X, and the second intermediate signal is formed at a second sensing element group arranged in the second sensing assembly 500 in the first direction X.

The first intermediate signal may be specifically a first intermediate signal op11 shown in FIG. 15 or FIG. 23 or a first intermediate signal op11′ shown in FIG. 20 or FIG. 25. The second intermediate signal may be specifically a second intermediate signal op12 shown in FIG. 15 or FIG. 23 or a second intermediate signal op12′ shown in FIG. 20 or FIG. 25.

One of the first sensing assembly 300 and the second sensing assembly 400 is relatively close to a first magnetic pole N; and the other of the first sensing assembly 300 and the second sensing assembly 400 is relatively away from the first magnetic pole N.

Step S2, performing at least a second operation according to the first intermediate signal and the second intermediate signal to determine first state data of a magnet to be detected.

In this way, based on configuration of a relative position of the sensing assembly with respect to the magnet to be detected 900 and configuration of an arrangement direction of the sensing elements in the sensing assembly, the current position, attitude or motion data of the magnet to be detected 900 can be determined in contrast with each other at least according to the two sets of intermediate signals output.

In an embodiment, the second operation op2 may be a differential operation, so that interfering magnetic fields carried by the two intermediate signals in a same direction can be eliminated and the overall anti-interference capability can be improved.

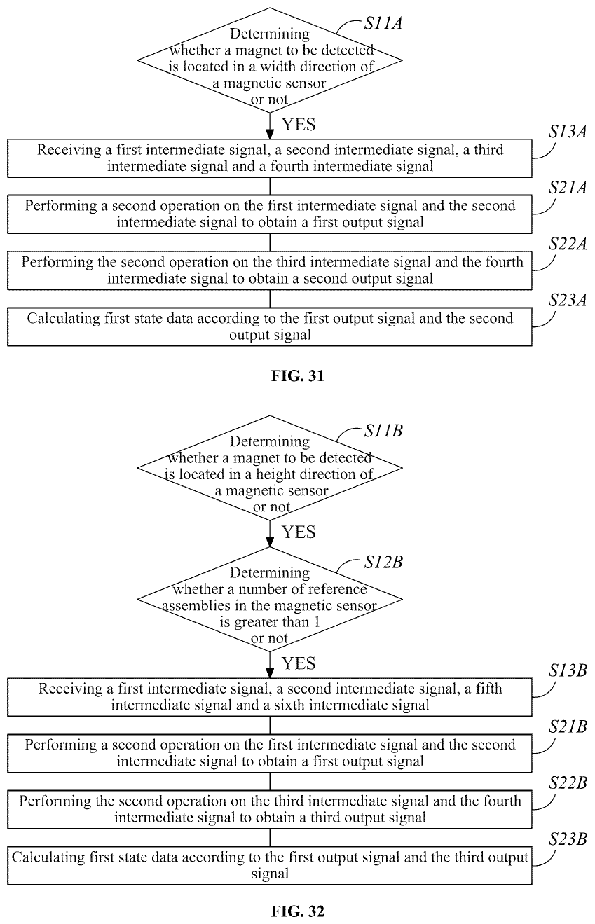

In an embodiment, with reference to FIGS. 30 and 31, the state detection method may specifically include the following steps.

Step S1, receiving a first intermediate signal and a second intermediate signal. Step S1 may specifically include:
step S11A: determining whether a magnet to be detected is located in a width direction of a magnetic sensor or not; and
if yes (i.e., if the magnet to be detected is located in a width direction of the magnetic sensor), skipping to step S13A, receiving a first intermediate signal, a second intermediate signal, a third intermediate signal and a fourth intermediate signal.

Step S2, performing at least a second operation according to the first intermediate signal and the second intermediate signal to determine first state data of a magnet to be detected. Step S2 may specifically include:
step S21A: performing a second operation on the first intermediate signal and the second intermediate signal to obtain a first output signal;
step S22A: performing the second operation on the third intermediate signal and the fourth intermediate signal to obtain a second output signal; and
step S23A: calculating first state data according to the first output signal and the second output signal.

As shown in FIGS. 18-20 or FIGS. 24 and 25, a first intermediate signal op11′ is formed by performing a second operation op2 on signals formed at a first sensing element group; a second intermediate signal op12′ is formed by performing the second operation op2 on signals formed at a second sensing element group; a third intermediate signal op23 is formed by performing the second operation op2 on signals formed at a third sensing element group arranged in the first sensing assembly in a second direction Y; and a fourth intermediate signal op24 is formed by performing the second operation op2 on signals formed at a fourth sensing element group arranged in the second sensing assembly in the second direction Y.

In an embodiment, the first direction X and the second direction Y are perpendicular to each other.

In an embodiment, the second operation op2 is a differential operation.

In an embodiment, step S23A may specifically include: calculating the first state data according to a first output signal o21′, a second output signal o22 and preset state correction information.

As previously described, upon determining that the magnet to be detected is located in the width direction of the magnetic sensor (specially, at one side in the width direction of the magnetic sensor), the calculation of the first state data may actually be completed only according to the first sensing element group and the second sensing element group, or only according to the third sensing element group and the fourth sensing element group. In an embodiment, the first intermediate signal and the second intermediate signal may be received only, the first output signal may be calculated only, and the first state data may be calculated according to the first output signal; and in another embodiment, the third intermediate signal and the fourth intermediate signal may be received only, the second output signal may be calculated only, and the first state data may be calculated according to the second output signal.

In an embodiment, with reference to FIGS. 30 and 32, the state detection method may specifically include the following steps.

Step S1, receiving a first intermediate signal and a second intermediate signal. Step S1 may specifically include:
step S11B: determining whether a magnet to be detected is located in a height direction of a magnetic sensor (specially, at one side in the height direction of the magnetic sensor) or not;
if yes (i.e., if the magnet to be detected is located in a height direction of the magnetic sensor), skipping to step S2B, determining whether a number of reference assemblies in the magnetic sensor is greater than 1 or not; and
if yes (i.e., if the number of the reference assemblies in the magnetic sensor is greater than 1), skipping to step S13B, receiving a first intermediate signal, a second intermediate signal, a fifth intermediate signal and a sixth intermediate signal.

Step S2, performing at least a second operation according to the first intermediate signal and the second intermediate signal to determine first state data of a magnet to be detected. Step S2 may specifically include:
step S21B: performing a second operation on the first intermediate signal and the second intermediate signal to obtain a first output signal;
step S22B: performing the second operation on the third intermediate signal and the fourth intermediate signal to obtain a third output signal; and
step S23B, calculating first state data according to the first output signal and the third output signal.

As shown in FIGS. 9-15, the reference assembly (for example, a first reference assembly 200 and/or a second reference assembly 400) includes a magnetic aggregation element and a reference element adjacent to an extension surface of the magnetic aggregation element. A center of at least one reference element is located at a position corresponding to an axis of symmetry of an extension surface of the magnetic aggregation element. In an embodiment, a projection of the center of at least one reference element onto the extension surface of the corresponding magnetic aggregation element is located at an axis of symmetry of the extension surface of the magnetic aggregation element. At least one of the reference assemblies is arranged at a carrying surface of the base plate 101.

A first intermediate signal op11 is formed by performing a first operation op1 on signals formed at a first sensing element group, a second intermediate signal op12 is formed by performing the first operation op1 on signals formed at a second sensing element group, the fifth intermediate signal is formed at a first reference element 25 in the first reference assembly 200, and the sixth intermediate signal is formed at a second reference element 45 in the second reference assembly 400.

In an embodiment, a center of the first reference element 25 is located at a plane where a magnetic pole interface of the magnet to be detected 900 is located. A center of the second reference element 45 is located at the plane where the magnetic pole interface is located.

In an embodiment, the first reference element 25 and the second reference element 45 are arranged at different positions of the base plate 101.

In an embodiment, the first operation op1 and the second operation op2 are inverse. In an example, the first operation op1 is a superposition operation and the second operation op2 is a differential operation.

In an embodiment, S23B may specifically include: calculating first state data according to a first output signal o21, a third output signal o23 and preset state correction information.

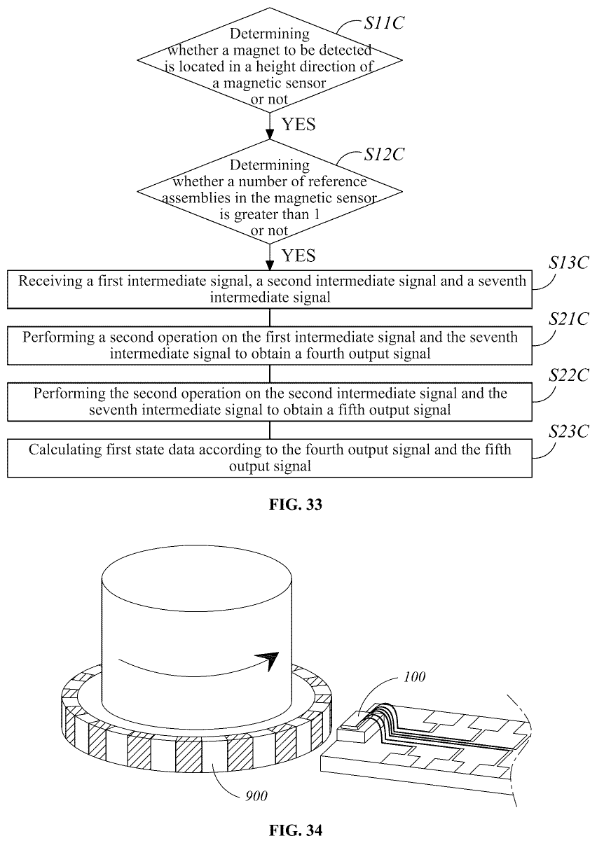

In an embodiment, with reference to FIGS. 30 and 33, the state detection method may specifically include the following steps.

Step S1, receiving a first intermediate signal and a second intermediate signal. Step S1 may specifically include:
step S11C: determining whether a magnet to be detected is located in a height direction of a magnetic sensor (specially, at one side in the height direction of the magnetic sensor) or not;
if yes (i.e., if the magnet to be detected is located in a height direction of the magnetic sensor), skipping to step S12C, determining whether a number of reference assemblies in the magnetic sensor is equal to 1 or not; and
if yes (i.e., if the number of reference assemblies in the magnetic sensor is equal to 1), skipping to step S13C, receiving a first intermediate signal, a second intermediate signal and a seventh intermediate signal.

Step S2, performing at least a second operation according to the first intermediate signal and the second intermediate signal to determine first state data of a magnet to be detected. Step S2 may specifically include:
step S21C: performing a second operation on the first intermediate signal and the seventh intermediate signal to obtain a fourth output signal;
step S22C: performing the second operation on the second intermediate signal and the seventh intermediate signal to obtain a fifth output signal; and
step S23C: calculating first state data according to the fourth output signal and the fifth output signal.

As shown in FIGS. 22 and 23, the reference assembly (for example, the first reference assembly 200) includes a magnetic aggregation element and a reference element adjacent to an extension surface of the magnetic aggregation element. A center of the reference element is located at a position corresponding to an axis of symmetry of an extension surface of the magnetic aggregation element. In an embodiment, a projection of the center of the reference element onto the extension surface of the corresponding magnetic aggregation element is located at an axis of symmetry of the extension surface of the magnetic aggregation element. The reference assembly is arranged at a carrying surface of the base plate 101.

A first intermediate signal op11 is formed by performing a first operation op1 on signals formed at a first sensing element group, a second intermediate signal op12 is formed by performing the first operation op1 on signals formed at a second sensing element group, and the seventh intermediate signal is formed at the reference element (for example, the first reference assembly 25).

In an embodiment, a center of the reference element is located at a plane where a magnetic pole interface of the magnet to be detected 900 is located.

In an embodiment, the first operation op1 and the second operation op2 are inverse. In an example, the first operation op1 is a superposition operation and the second operation op2 is a differential operation.

In an embodiment, S23B may specifically include: calculating first state data according to a fourth output signal o24, a fifth output signal o25 and preset state correction information.

The above three technical solutions may be implemented successively or concurrently. For the former scenario, where technical solutions are implemented successively, after determining that conditions of one technical solution are not satisfied, the circuit connection relationship may be switched by operation to execute another technical solution instead. For the latter scenario, where technical solutions are implemented concurrently, a single magnetic sensor or state detection apparatus may be provided with at least one set of sensing assembly and/or reference assembly that can meet requirements of each of the above three technical solutions.

The present invention provides test and measurement systems, as shown in FIGS. 34-36, to describe application scenarios of the magnetic sensor and the state detection apparatus provided by the present invention. However, it can be understood that the magnetic sensor and the state detection apparatus provided by the present invention are not limited to the following scenarios, and in other words, not limited to being implemented in the test and measurement systems provided below.

As shown in FIG. 34, a test and measurement system may be configured as a magnetic rotary encoder system. A knob is formed at a magnet to be detected 900, and the knob can be rotated to change a relative position of a magnetic pole on the magnet to be detected 900 with respect to the magnetic sensor 100, thereby completing encoding.

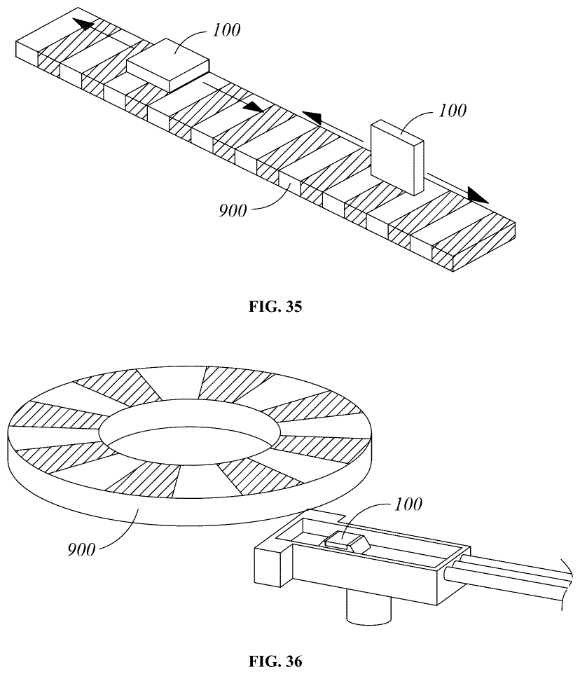

As shown in FIG. 35, a test and measurement system may be configured as a magnetic scale system. The magnet to be detected 900 may be formed into a strip shape. An extension surface of the magnetic sensor 100 may be parallel or perpendicular to an extension surface of the magnet to be detected 900. The magnet to be detected 900 is used as a magnetic scale, the magnetic sensor 100 is used as a magneto-resistive head (MR), and the two move relative to each other (either of the two is moved or both of the two are moved simultaneously), such that a number of magnetic waves can be calculated.

As shown in FIG. 36, the test and measurement system may be configured as a magnetic field generating system. The magnet to be detected 900 may be configured as a multipole magnet, particularly a radial multipole magnetic ring. The magnetic field generating system may be specifically used in scenarios such as magnetization of a multipole magnetic ring, generation of a radial gradient magnetic field, or magnetic guidance of a rotating magnetic field. Based on the different number of magnet poles, the magnetic field generating system may be used in apparatuses such as home appliances, motors and encoders. In particular, when configured as a radial 8-pole magnetic ring, the magnetic field generating system may be carried in a hybrid vehicle, and the magnetic sensor 100 correspondingly detects the distribution of magnetic fields.

It can be understood that in the present invention, the first state may be any relative state such as an initial state, a state of termination or an intermediate state of the magnet to be detected 900.

It can be understood that in the present invention, the magnet to be detected may be strip-shaped, disc-shaped or ring-shaped.

In summary, the magnetic sensor provided by the present invention enables adjustment of the directions of magnetic induction lines at the sensing elements by arranging the magnetic aggregation elements near the sensing elements, thereby being suitable for the sensing elements with different sensing directions, and eliminating restrictions in manufacture and use of the magnetic sensor. According to the magnetic sensor provided by the present invention, the two sets of sensing assemblies having different relative positional relationships with the first magnetic pole on the magnet to be detected can form a contrast with each other to achieve an anti-interference effect.

It should be understood that, although the description is described in terms of the embodiments, each of the embodiments is not intended to contain an independent technical solution. Such description manner of the description is merely intended for clarity. Those skilled in the art should take the description as a whole, and the technical solutions in respective embodiments may also be combined appropriately to form other embodiments understandable by those skilled in the art.

The series of detailed descriptions listed above are merely specifically illustrative of the possible embodiments of the present invention, and are not intended to limit the protection scope of the present invention. The equivalent embodiments or alterations made without departing from the technology and spirit of the present invention should be included within the protective scope of the present invention.

What is claimed is:

1. A magnetic sensor, comprising:
a sensing assembly comprising a magnetic aggregation element and at least one sensing element adjacent to an extension surface of the magnetic aggregation element;
a base plate, on a carrying surface of which at least two of the sensing assemblies are arranged; and
when the magnetic sensor approaches a magnet to be detected, one of the sensing assemblies is relatively close to a first magnetic pole of the magnet to be detected and another of the sensing assemblies is relatively away from the first magnetic pole, at least in a first state.

2. The magnetic sensor according to claim 1, wherein the extension surface of the magnetic aggregation element abuts against the carrying surface of the base plate; and the sensing element is arranged between a corresponding magnetic aggregation element and the base plate.

3. The magnetic sensor according to claim 1, wherein n sensing elements are arranged to correspond to a single sensing assembly, where n≥2; the sensing elements are arranged symmetrically relative to a central axis of a corresponding magnetic aggregation element; and
when n is an odd number, a central axis of one of the sensing elements is aligned with a central axis of a corresponding magnetic aggregation element, and rest (n−1) sensing elements are arranged symmetrically relative to a central axis of the corresponding magnetic aggregation element.

4. The magnetic sensor according to claim 1, wherein the magnet to be detected is arranged in a height direction of the magnetic sensor; and in the first state, the sensing assemblies are symmetrical relative to a magnetic pole interface of the magnet to be detected.

5. The magnetic sensor according to claim 1, wherein the magnet to be detected is arranged in a height direction of the magnetic sensor; and in the first state, a first sensing assembly is relatively close to the first magnetic pole and comprises a first sensing element group arranged in a first direction, and a second sensing assembly is relatively away from the first magnetic pole and comprises a second sensing element group arranged in the first direction; and
at least one of a first intermediate signal formed by performing a first operation on signals formed at the first sensing element group, a second intermediate signal formed by performing a first operation on signals formed at the second sensing element group, and a first output signal formed by performing a second operation on a first intermediate signal and a second intermediate signal is used for calculating first state data of the magnet to be detected.

6. The magnetic sensor according to claim 5, wherein the first operation and the second operation are inverse; the first operation is a superposition operation, and the second operation is a differential operation; the first direction is perpendicular to a movement direction of a part at the magnet to be detected which corresponds to the sensing element;
the first sensing assembly comprises a first magnetic aggregation element, and the first sensing element group comprises at least two sensing elements arranged on two sides of the first magnetic aggregation element in the first direction; and the second sensing assembly comprises a second magnetic aggregation element, and the second sensing element group comprises at least two sensing elements arranged on two sides of the second magnetic aggregation element in the first direction.

7. The magnetic sensor according to claim 1, wherein the magnet to be detected is arranged in a width direction of the magnetic sensor, and in the first state, the sensing assembly is aligned with the magnet to be detected in a height direction of the magnetic sensor.

8. The magnetic sensor according to claim 1, wherein the magnet to be detected is arranged in a width direction of the magnetic sensor; in the first state, a first sensing assembly is relatively away from the first magnetic pole and comprises a first sensing element group arranged in a first direction, and a second sensing assembly is relatively close to the first magnetic pole and comprises a second sensing element group arranged in the first direction; and
at least one of a first intermediate signal formed by performing a second operation on signals formed at the first sensing element group, a second intermediate signal formed by performing a second operation on signals formed at the second sensing element group, and a first output signal formed by performing a second operation on a first intermediate signal and a second intermediate signal is used for calculating first state data of the magnet to be detected.

9. The magnetic sensor according to claim 8, wherein in the first state, the first sensing assembly comprises a third sensing element group arranged in a second direction, and the second sensing assembly comprises a fourth sensing element group arranged in the second direction;
at least one of a third intermediate signal formed by performing a second operation on signals formed at the third sensing element group, a fourth intermediate signal formed by performing a second operation on signals formed at the fourth sensing element group, and a second output signal formed by performing a second operation on a third intermediate signal and a fourth intermediate signal is used for calculating first state data of the magnet to be detected;
wherein the second operation is a differential operation, the first direction and the second direction are perpendicular to each other; the first direction is perpendicular to a movement direction of a part at the magnet to be detected which corresponds to the sensing element;
the first sensing assembly comprises a first magnetic aggregation element, the first sensing element group comprises two sensing elements arranged on two sides of the first magnetic aggregation element in the first direction, and the third sensing element comprises two sensing elements arranged on two sides of the first magnetic aggregation element in the second direction; and the second sensing assembly comprises a second magnetic aggregation element, the second sensing element group comprises at least two sensing elements arranged on two sides of the second magnetic aggregation element in the first direction, and the fourth sensing element group comprises at least two sensing elements arranged on two sides of the second magnetic aggregation element in the second direction.

10. The magnetic sensor according to claim 1, wherein sensing elements are configured to be of a same structure, and/or sensing assemblies are configured to be of a same structure; and the sensing element is configured to at least partially overlap an extension surface of a corresponding magnetic aggregation element.

11. The magnetic sensor according to claim 1, comprising:
a reference assembly, comprising a magnetic aggregation element and a reference element adjacent to an extension surface of the magnetic aggregation element;
wherein a center of at least one reference element is configured to be at a position corresponding to an axis of symmetry of the extension surface of the magnetic aggregation element; and at least one of the reference assemblies is arranged at a carrying surface of the base plate.

12. The magnetic sensor according to claim 11, wherein the reference element is arranged between a corresponding magnetic aggregation element and the base plate; the magnet to be detected is arranged in a height direction of the magnetic sensor; and in the first state, an axis of symmetry of the extension surface of the magnetic aggregation element of the reference assembly is located at a plane where a magnetic pole interface of the magnet to be detected is located.

13. The magnetic sensor according to claim 11, wherein the magnet to be detected is arranged in a height direction of the magnetic sensor; in the first state, the first reference assembly comprises a first reference element and a center of the first reference element is located at a plane where a magnetic pole interface of the magnet to be detected is located, and the second reference assembly comprises a second reference element and a center of the second reference is located at a plane where the magnetic pole interface is located; the first reference element and the second reference element are arranged at different positions of the base plate; and
at least one of a fifth intermediate signal formed at the first reference element, a sixth intermediate signal formed at the second reference element, and a third output signal formed by performing a second operation on a fifth intermediate signal and a sixth intermediate signal is used for calculating first state data of the magnet to be detected.

14. The magnetic sensor according to claim 11, wherein the magnet to be detected is arranged in a height direction of the magnetic sensor; a reference element is arranged on the base plate; in the first state, a first sensing assembly is relatively close to the first magnetic pole and comprises a first sensing element group arranged in a first direction, and a second sensing assembly is relatively away from the first magnetic pole and comprises a second sensing element group arranged in the first direction; and
at least one of a first intermediate signal formed by performing a first operation on signals formed at the first sensing element group, a second intermediate signal formed by performing a first operation on signals formed at the second sensing element group, a seventh intermediate signal formed at the reference element, a fourth output signal formed by performing a second operation on a first intermediate signal and a seventh intermediate signal, and a fifth output signal formed by performing a second operation on a second intermediate signal and a seventh intermediate signal is used for calculating first state data of the magnet to be detected.

15. The magnetic sensor according to claim 11, wherein in the first state, the first sensing assembly is relatively close to the first magnetic pole; and the first sensing assembly is at a first relative distance away from the first magnetic pole, the reference assembly is at a second relative distance away from the first magnetic pole, and the second relative distance is equal to or greater than the first relative distance.

16. The magnetic sensor according to claim 11, wherein the sensing element and the reference element are configured to be of a same structure, and/or the sensing assembly and the reference assembly are configured to be of a same structure; and the reference element is configured to at least partially overlap an extension surface of a corresponding magnetic aggregation element.

17. The magnetic sensor according to claim 1, wherein a sensing direction of the sensing element is perpendicular to an extension surface of a corresponding magnetic aggregation element.

18. The magnetic sensor according to claim 1, wherein the sensing element comprises at least one Hall unit; a charge deflecting electrode at the Hall unit is configured to form a first Hall output, and a charge repelling electrode at the Hall unit is configured to form a second Hall output; and the sensing assembly takes the first Hall output and the second Hall output as signal outputs of the corresponding sensing element.

19. The magnetic sensor according to claim 18, wherein the sensing element comprises two Hall units or four Hall units; and at the Hall units, the charge deflecting electrodes are coupled to each other, the charge repelling electrodes are coupled to each other, power supply electrodes are coupled to each other, and reference electrodes are coupled to each other.

20. A state detection apparatus, comprising a magnetic sensor according to claim 1 and configured to determine, according to an output of the magnetic sensor, current state data of a magnet to be detected; wherein the state data includes at least one of angle, velocity, acceleration and rotation stroke length.

21. The state detection apparatus according to claim 20, comprising:
a storage module configured to store state correction information; and
an output processing module coupled to the magnetic sensor and configured to receive an output signal of the magnetic sensor and calculate the state data according to the output signal of the magnetic sensor, or coupled to the magnetic sensor and the storage module, and configured to adjust the state data according to the state correction information.

22. A state detection method applied to a magnetic sensor according to claim 1 and comprising:
receiving a first intermediate signal and a second intermediate signal, wherein the first intermediate signal is formed at a first sensing element group arranged in a first sensing assembly in a first direction, the second intermediate signal is formed at a second sensing element group arranged in a second sensing assembly in the first direction, one of the first sensing assembly and the second sensing assembly is relatively close to the first magnetic pole, and the other of the first sensing assembly and the second sensing assembly is relatively away from the first magnetic pole; and
performing at least a second operation according to the first intermediate signal and the second intermediate signal to determine first state data of a magnet to be detected.

23. The state detection method according to claim 22, wherein the second operation comprises a differential operation.

24. The state detection method according to claim 22, wherein receiving a first intermediate signal and a second intermediate signal specifically comprises:
determining whether a magnet to be detected is located in a width direction of the magnetic sensor or not; and
if yes, receiving a first intermediate signal, a second intermediate signal, a third intermediate signal and a fourth intermediate signal, wherein the first intermediate signal is formed by performing a second operation on signals formed at the first sensing element group; the second intermediate signal is formed by performing the second operation on signals formed at the second sensing element group; the third intermediate signal is formed by performing the second operation on signals formed at a third sensing element group arranged in the first sensing assembly in a second direction; the fourth intermediate signal is formed by performing the second operation on signals formed at a fourth sensing element group arranged in the second sensing assembly in the second direction; and the first direction and the second direction are perpendicular to each other;
performing at least a second operation according to the first intermediate signal and the second intermediate signal to determine first state data of a magnet to be detected specifically comprises:
performing a second operation on the first intermediate signal and the second intermediate signal to obtain a first output signal;
performing the second operation on the third intermediate signal and the fourth intermediate signal to obtain a second output signal; and
calculating first state data according to the first output signal and the second output signal.

25. The state detection method according to claim 22, wherein receiving a first intermediate signal and a second intermediate signal specifically comprises:
determining whether a magnet to be detected is located in a height direction of the magnetic sensor or not;
if yes, determining whether a number of reference assemblies in the magnetic sensor is greater than 1 or not, wherein the reference assembly comprises a magnetic aggregation element and a reference element adjacent to an extension surface of the magnetic aggregation element, a center of at least one reference element is located at a position corresponding to an axis of symmetry of the extension surface of the magnetic aggregation element, and at least one of the reference assemblies is arranged at a carrying surface of the base plate;
if yes, receiving a first intermediate signal, a second intermediate signal, a fifth intermediate signal and a sixth intermediate signal, wherein the first intermediate signal is formed by performing a first operation on signals formed at the first sensing element group, the second intermediate signal is formed by performing the first operation on signals formed at the second sensing element group, the fifth intermediate signal is formed at a first reference element in a first reference assembly, and the sixth intermediate signal is formed at a second reference element in a second reference assembly; a center of the first reference element is located at a plane where a magnetic pole interface of the magnet to be detected is located, and a center of the second reference element is located at a plane where the magnetic pole interface is located; the first reference element and the second reference element are arranged at different positions of the base plate; and the first operation and the second operation are inverse;
performing at least a second operation according to the first intermediate signal and the second intermediate signal to determine first state data of a magnet to be detected specifically comprises:
performing a second operation on the first intermediate signal and the second intermediate signal to obtain a first output signal;
performing the second operation on the fifth intermediate signal and the sixth intermediate signal to obtain a third output signal; and
calculating first state data according to the first output signal and the third output signal.

26. The state detection method according to claim 22, wherein receiving a first intermediate signal and a second intermediate signal specifically comprises:
determining whether a magnet to be detected is located in a height direction of the magnetic sensor or not;
if yes, determining whether a number of reference assemblies in the magnetic sensor is equal to 1 or not, wherein the reference assembly comprises a magnetic aggregation element and a reference element adjacent to an extension surface of the magnetic aggregation element, a center of the reference is located at a position corresponding to an axis of symmetry of the extension surface of the magnetic aggregation element, and the reference assembly is arranged at a carrying surface of the base plate;
if yes, receiving a first intermediate signal, a second intermediate signal and a seventh intermediate signal, wherein the first intermediate signal is formed by performing a first operation on signals formed at the first sensing element group, the second intermediate signal is formed by performing the first operation on signals formed at the second sensing element group, the seventh intermediate signal is formed at the reference element, a center of the reference element is located at a plane where a magnetic pole interface of the magnet to be detected is located, and the first operation and the second operation are inverse;
performing at least a second operation according to the first intermediate signal and the second intermediate signal to determine first state data of a magnet to be detected specifically comprises:
performing a second operation on the first intermediate signal and the seventh intermediate signal to obtain a fourth output signal;
performing the second operation on the second intermediate signal and the seventh intermediate signal to obtain a fifth output signal; and
calculating first state data according to the fourth output signal and the fifth output signal.
